(19) United States
(12) Patent Application Publication
(10) Pub. No.: US 2016/0148947 A1
(43) Pub. Date: May 26, 2016

(54) MEMORY DEVICES AND METHODS OF MANUFACTURING THE SAME

(71) Applicants: Jun-Ho SEO, Suwon-Si (KR); Daewoong KANG, Seoul (KR); Hyoje BANG, Seoul (KR); Changsub LEE, Hwaseong-Si (KR); Sunghoi HUR, Seoul (KR)

(72) Inventors: Jun-Ho SEO, Suwon-Si (KR); Daewoong KANG, Seoul (KR); Hyoje BANG, Seoul (KR); Changsub LEE, Hwaseong-Si (KR); Sunghoi HUR, Seoul (KR)

(21) Appl. No.: 14/845,541

(22) Filed: Sep. 4, 2015

(30) Foreign Application Priority Data
Nov. 20, 2014 (KR) 10-2014-0162643

(51) Int. Cl. H01L 27/115

(52) U.S. Cl. CPC H01L 27/11568; H01L 27/11582

(57) ABSTRACT

A memory device includes a stack including gate electrodes vertically stacked on a substrate and having a vertical hole, an active pillar disposed in the vertical hole and providing a vertical channel, a charge storage section interposed between the active pillar and the gate electrodes, a blocking dielectric interposed between the charge storage section and the gate electrodes, a tunnel dielectric interposed between the charge storage section and the active pillar, insulation filling an inner hole of the active pillar, and a fixed charge layer interposed between the filling insulation and the active pillar. Measures are taken to address phenomena in which current would otherwise be adversely affected near an interface between the vertical channel and the filling insulation.

### PRIORITY STATEMENT

This U.S. non-provisional patent application claims priority under 35 U.S.C. §119 to Korean Patent Application No. 10-2014-0162643, filed on Nov. 20, 2014, in the Korean Intellectual Property Office, the disclosure of which is hereby incorporated by reference in its entirety.

### BACKGROUND

The inventive concepts relate to semiconductor devices and methods of manufacturing the same. More particularly, the inventive concepts relate to three dimensional (3D) non-volatile memory devices and methods of manufacturing the same.

The integration density of semiconductor memory devices may be proportional to the cost of the semiconductor memory devices. A conventional two-dimensional (2D) memory device includes a planar array of unit memory cells formed of fine patterns of certain elements and features. The integration density of such a conventional two-dimensional (2D) memory device mainly corresponds to the area occupied by a unit memory cell of the device. Thus, the degree to which the integration density of a 2D memory device can be increased greatly depends on advances in techniques of forming fine patterns. However, apparatuses for forming fine patterns are very expensive to begin with and the cost of these apparatuses will only increase along with the fineness of the patterns that they are able to produce. Therefore, manufacturing costs may impose limits in the extent to which the integration densities of 2D memory devices are increased. In light of this, three-dimensional (3D) semiconductor devices have been developed. Three-dimensional (3D) semiconductor memory devices provide high integration densities and excellent performance while being relative inexpensive to manufacture per unit memory cell.

### SUMMARY

According to one aspect of the inventive concept, a memory device includes a substrate, a stack including gate electrodes vertically stacked on the substrate, the stack having a vertical hole exposing a portion of the substrate, an active pillar including a bottom portion disposed in a lower region of the vertical hole and a vertical portion extending along sides of the vertical hole, the active pillar having an inner hole, a charge storage section interposed between the active pillar and the gate electrodes, a blocking dielectric interposed between the charge storage section and the gate electrodes, a tunnel dielectric interposed between the charge storage and the active pillar, filling insulation filling the inner hole, and a fixed charge layer interposed between the filling insulation and the active pillar, and in which the fixed charge layer extends onto the bottom portion of the active pillar, and the vertical portion of the active pillar is thicker than the bottom portion of the active pillar.

According to another aspect of the inventive concepts, a memory device includes a substrate, a stack including gate electrodes vertically stacked on the substrate, the stack having a vertical hole exposing a portion of the substrate, an active pillar disposed in the vertical hole and having an inner hole, a charge storage section interposed between the active pillar and the gate electrodes, a blocking dielectric interposed between the charge storage section and the gate electrodes, a tunnel dielectric interposed between the charge storage section and the active pillar, and filling insulation filling the inner hole, and in which the active pillar includes a first semiconductor pattern adjacent to the filling insulation layer, and a second semiconductor pattern interposed between the first semiconductor pattern and the tunnel dielectric, and a dopant concentration of the second semiconductor pattern is different from that of the first semiconductor pattern.

According to still another aspect of the inventive concepts, a memory device includes a substrate, a stack including gate electrodes vertically stacked on the substrate, the stack having a vertical hole exposing a portion of the substrate, an active pillar disposed in the vertical hole and having an inner hole, a charge storage layer interposed between the active pillar and the gate electrodes, a blocking dielectric interposed between the charge storage layer and the gate electrodes, a tunnel dielectric interposed between the charge storage layer and the active pillar, and filling insulation layer filling the inner hole, and in which the active pillar includes a first semiconductor pattern adjacent to the filling insulation layer, and a second semiconductor pattern interposed between the first semiconductor pattern and the tunnel dielectric, and the second semiconductor pattern is of material differing from the material of the first semiconductor pattern.

### BRIEF DESCRIPTION OF THE DRAWINGS

The inventive concepts will become more apparent in view of the attached drawings and accompanying detailed description.

FIG. 1 is a schematic block diagram illustrating embodiments of a memory device according to the inventive concepts;

FIG. 2 is a perspective view illustrating an embodiment of a memory cell array of FIG. 1;

FIG. 3 is a circuit diagram illustrating a cell array of a memory block of FIG. 2 according to the inventive concepts;

FIG. 4A is a perspective view of an embodiment of a memory device according the inventive concepts;

FIG. 4B is a plan view of the memory device;

FIG. 4C is a cross-sectional view taken along line IT of FIG. 4B;

FIG. 4D is an enlarged view of portion ‘A’ of the device in FIG. 4C;

FIG. 4E is an enlarged view of an example of portion ‘B’ of the device in FIG. 4D;

FIGS. 5A-12B illustrate a method of manufacturing a memory device according to the inventive concepts, wherein FIGS. 5A, 6A, 7A, 8A, 9A, 10A, 11A and 12A are cross-sectional views of the device during the course of its manufacture as each taken in a direction along a line corresponding to line I-I′ of FIG. 4B, and FIGS. 5B, 6B, 7B, 8B, 9B, 10B, 11B and 12B are enlarged views of portions ‘A’ of FIGS. 5A to 12A, respectively;

FIGS. 13A, 13B, 13C, and 13D are enlarged views of portions of different examples of a data storage element corresponding to portion ‘A’ of FIG. 4C;

FIG. 14 is a circuit diagram of another example of a cell array of a memory block of FIG. 2 according to the inventive concepts;

FIG. 15A is a cross-sectional view of other embodiments of a memory device including cell arrays of FIG. 14 according to the inventive concepts;

FIG. 15B is an enlarged view of the portion ‘A’ of the device shown in FIG. 15A;

FIGS. 16A-21B illustrate another embodiment of a method of manufacturing a memory device according to the inventive concepts, wherein FIGS. 16A, 17A, 18A, 19A, 20A and 21A are cross-sectional views of the device during the course of its manufacture, and FIGS. 16B, 17B, 18B, 19B, 20B and 21B are enlarged views of portions ‘A’ of FIGS. 16A to 21A, respectively;

FIGS. 22A-24B illustrate another embodiment of a method of manufacturing a memory device according to the inventive concepts, wherein FIGS. 22A, 23A and 24A are cross-sectional views of the device during the course of its manufacture, and FIGS. 22B, 23B and 24B are enlarged views of portions ‘A’ of FIGS. 22A to 24A, respectively;

FIG. 25 is a schematic block diagram of an example of an electronic system including a memory device according to the inventive concepts;

FIG. 26 is a schematic block diagram of an example of a memory card including a memory device according to the inventive concepts; and

FIG. 27 is a schematic block diagram of an example of an information processing system including a memory device according to the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. Likewise, it will be understood that when an element is referred to as being “connected” or “coupled” to another element, it can be directly connected or coupled to the other element or intervening elements may be present. In contrast, the term “directly” means that there are no intervening elements. Moreover, it will be understood that the “connections” described herein generally refer to electrical connections as the context will make clear even when not explicitly stated. The term “extending” will generally be referring to the longest dimension of an element or feature, i.e., the longitudinal direction of the element or feature, especially in the case in which the element or feature has a linear shape.

It will be further understood that when materials are referred to as being “different” or “differing” from one another, such a description refers to the materials having different properties from one another. Most notably, the different properties are different conductivities. As is clear from the various disclosed examples, the differences may be the result of the materials being of the same composition but having impurities (i.e., being doped) at different concentrations, as the result of the materials having different compositions and/or as the result of the materials having the same compositions but wherein the atomic percentages of elements differ among the materials, etc.

It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of representative embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

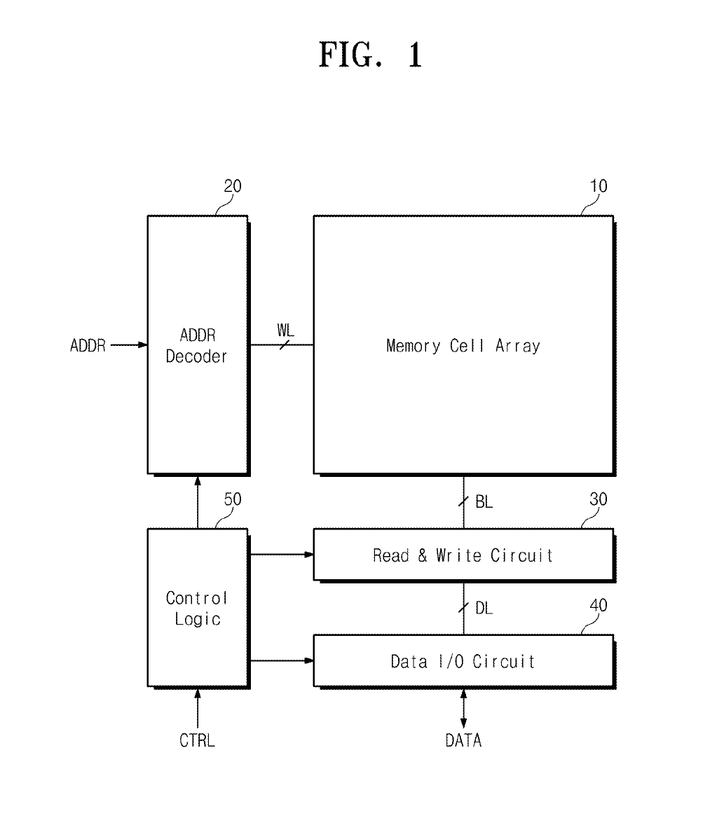

FIG. 1 is a schematic block diagram representative of a memory device according to the inventive concepts. Referring to FIG. 1, a representative memory device according to the inventive concepts may include a memory cell array 10, an address decoder 20, a read/write circuit 30, a data input/output (I/O) circuit 40, and a control logic circuit 50.

The memory cell array 10 may be connected to the address decoder 20 through a plurality of word lines WL and may be connected to the read/write circuit 30 through bit lines BL. The memory cell array 10 includes a plurality of memory cells. Each memory cell may be configured to store one or more bits.

The address decoder 20 may be connected to the memory cell array 10 through the word lines WL. The address decoder 20 may be configured to be operated in response to a control signal of the control logic circuit 50. The address decoder 20 may receive address signals ADDR from an external system. The address decoder 20 may decode a row address signal of the received address signals ADDR to select a corresponding one of the plurality of word lines WL. In addition, the address decoder 20 may decode a column address signal of the received address signals ADDR and may transmit the decoded column address signal to the read/write circuit 30. For example, the address decoder 20 may include known components such as a row decoder, a column decoder, and an address buffer.

The read/write circuit 30 may be connected to the memory cell array 10 through the bit lines BL and may be connected to the data I/O circuit 40 through data lines DL. The read/write circuit 30 may be operated in response to a control signal of the control logic circuit 50. The read/write circuit 30 may be configured to receive the column address signal decoded in the address decoder 20. The read/write circuit 30 may select one of the bit lines BL by means of the decoded column address signal. For example, the read/write circuit 30 may receive data from the data I/O circuit 40 and may store the received data in the memory cell array 10. In addition, the read/write circuit 30 may read data from the memory cell array 10 and may transmit the read data to the data I/O circuit 40. The read/write circuit 30 may read data from a first storing region of the memory cell array 10 and may write the read data in a second storing region of the memory cell array 10. For example, the read/write circuit 30 may be configured to perform a copy-back operation.

The read/write circuit 30 may include components such as a page buffer (or a page register) and a column selection circuit. In other examples, the read/write circuit 30 includes a sense amplifier, a write driver, and a column selection circuit.

The data I/O circuit 40 may be connected to the read/write circuit 30 through the data lines DL. The data I/O circuit 40 may be operated in response to a control signal of the control logic circuit 50. The data I/O circuit 40 may be configured to exchange data DATA with an external system. The data I/O circuit 40 may transmit the data DATA inputted from the external system to the read/write circuit 30 through the data lines DL. The data I/O circuit 40 may output the data DATA, transmitted from the read/write circuit 30 through the data lines DL, to the external system. For example, the data I/O circuit 40 may include a component such as a data buffer.

The control logic circuit 50 may be connected to the address decoder 20, the read/write circuit 30, and the data I/O circuit 40. The control logic circuit 50 may be configured to control operations of the memory device. The control logic circuit 50 may be operated in response to a control signal CTRL transmitted through the external system.

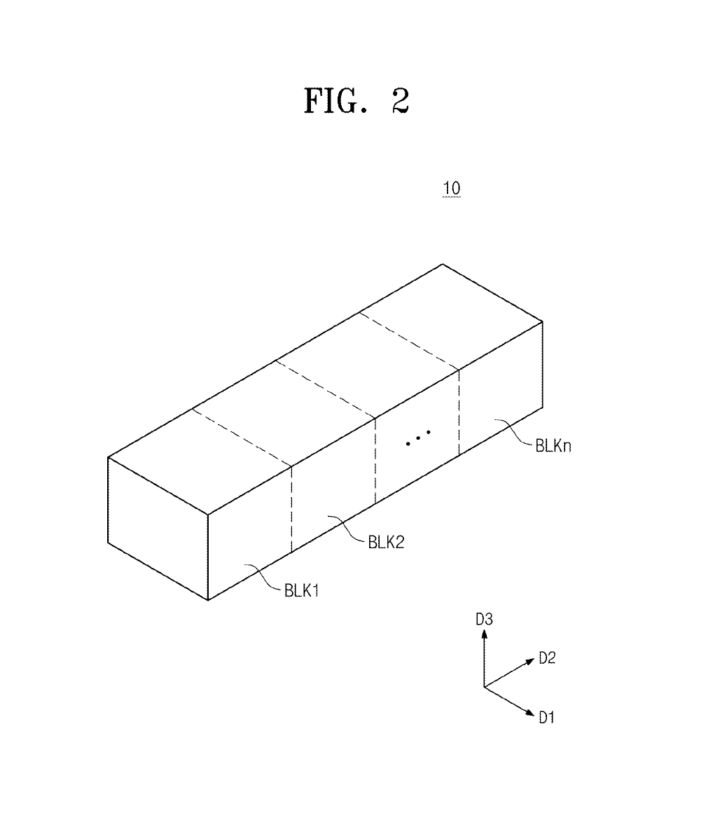

FIG. 2 is a perspective view of an example of a memory cell array 10 of the device of FIG. 1. Referring to FIG. 2, the memory cell array 10 may include a plurality of memory blocks BLK1 to BLKn. Each of the memory blocks BLK1 to BLKn may have a three-dimensional (3D) structure (or a vertical structure). For example, each of the memory blocks BLK1 to BLKn may include structures extending in first, second, and third directions D1, D2, and D3 intersecting each other. For example, each of the memory blocks BLK1 to BLKn may include a plurality of cell strings extending in the third direction D3.

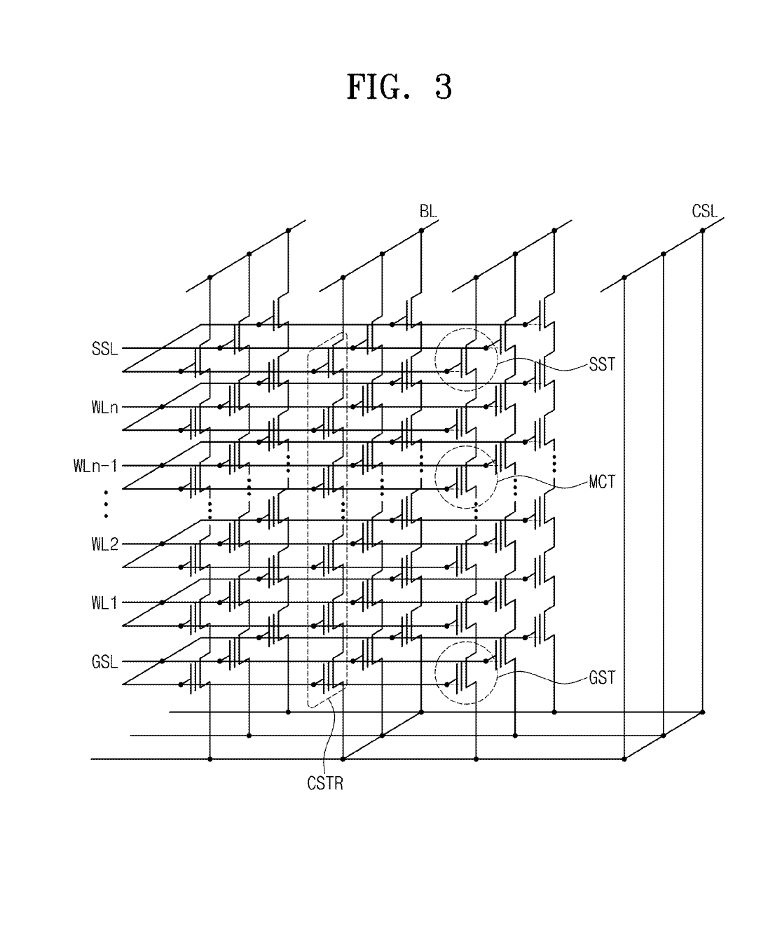

FIG. 3 is a schematic circuit diagram of an example of a memory block of the cell array 10 of FIG. 2. Referring to FIG. 3, the memory block may include a common source line CSL, bit lines BL, and a plurality of cell strings CSTR disposed between the common source line CSL and the bit lines BL. A plurality of cell strings CSTR may be connected in parallel to each of the bit lines BL.

Each of the cell strings CSTR may include a ground selection transistor GST connected to the common source line CSL, a string selection transistor SST connected to each of the bit lines BL, and a plurality of memory cell transistors MCT connected between the selection transistors GST and SST. The ground selection transistor GST, the memory cell transistors MCT, and the string selection transistor SST may be connected in series to each other. A ground selection line GSL, a plurality of word lines WL1 to WLn, and a string selection line SSL may correspond to gate electrodes of the ground selection transistor GST, the memory cell transistors MCT, and the string selection transistor SST, respectively.

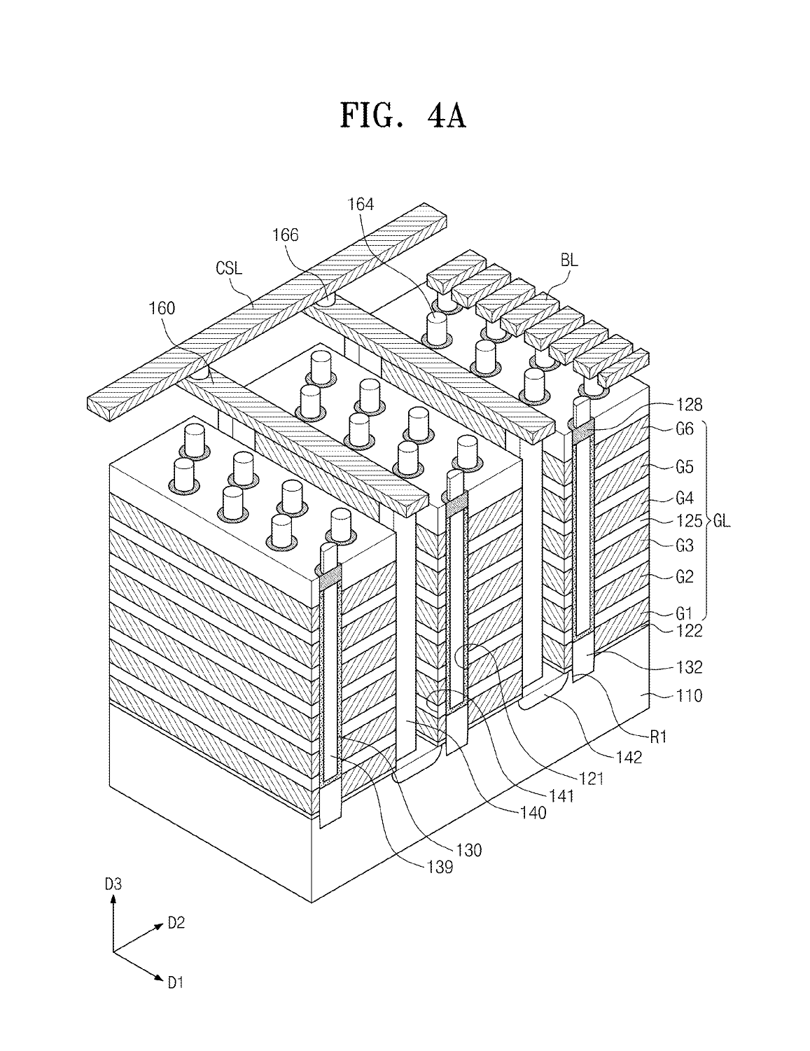

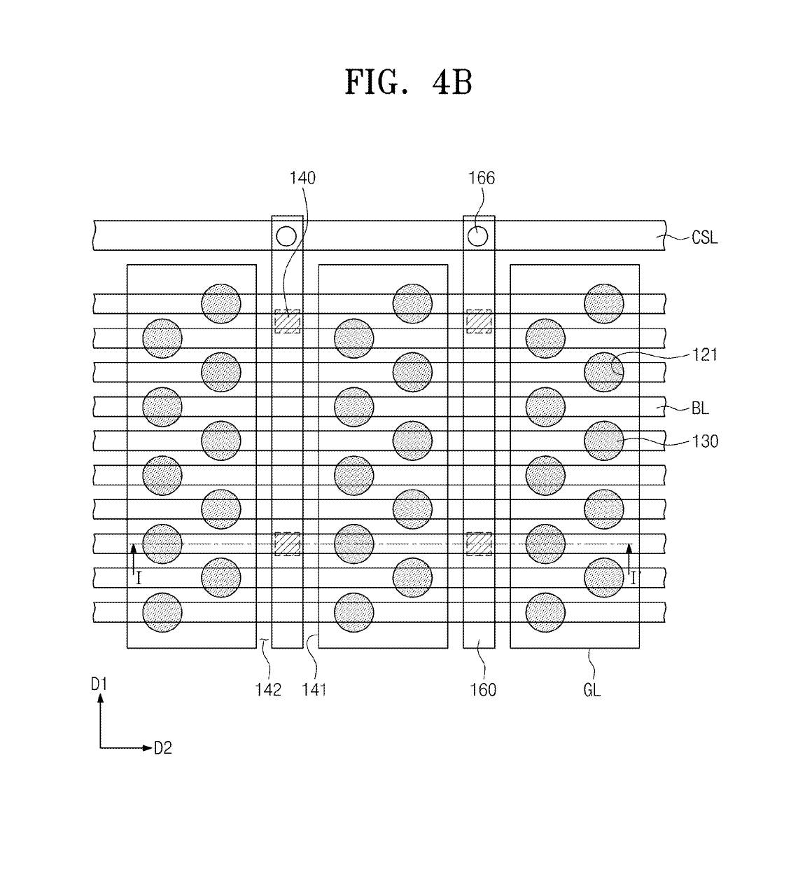

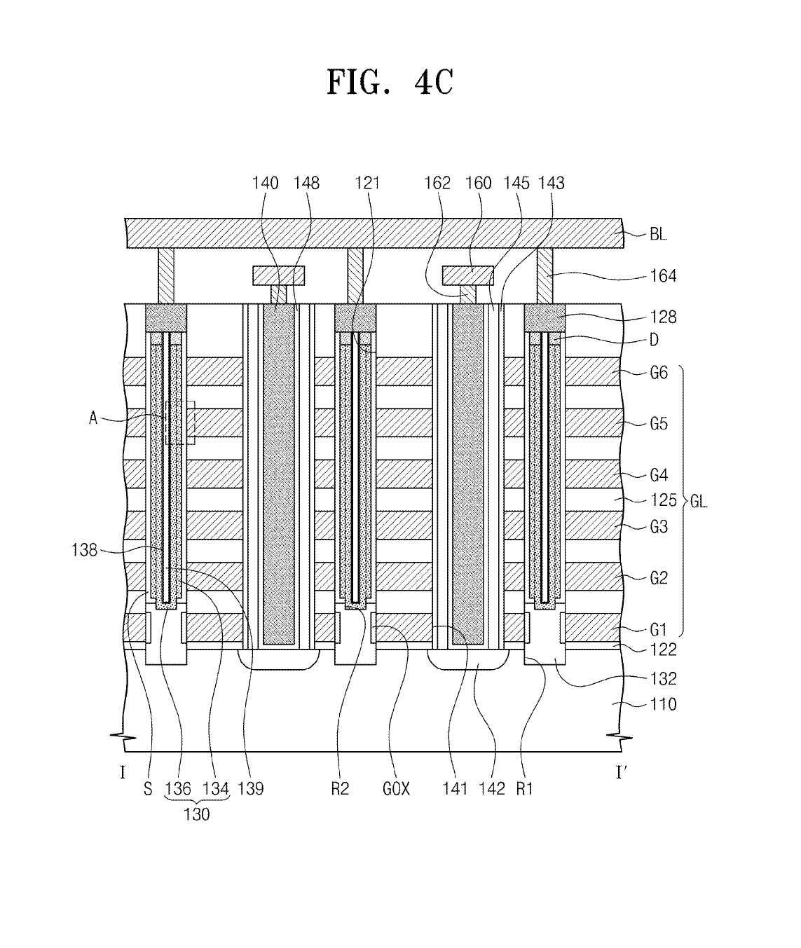

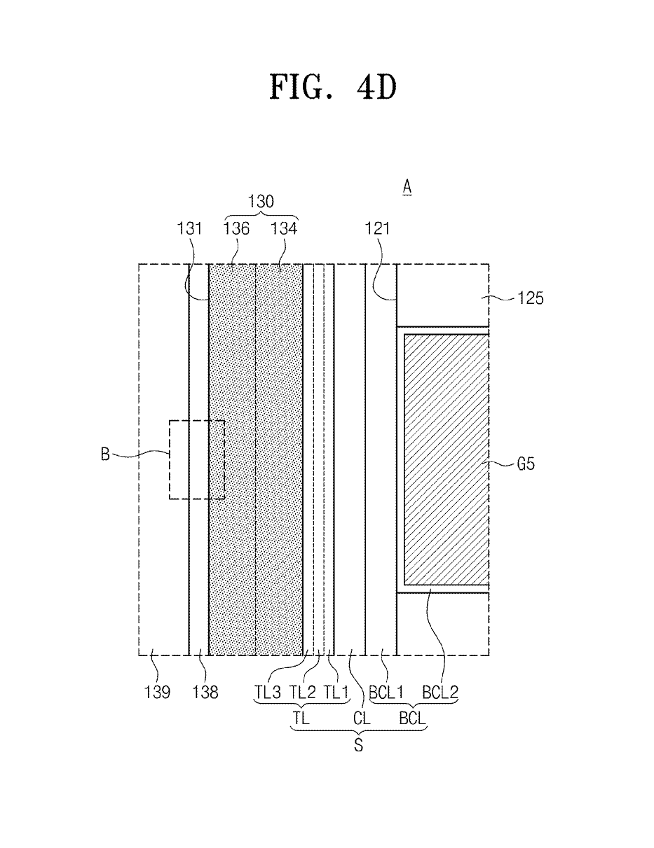

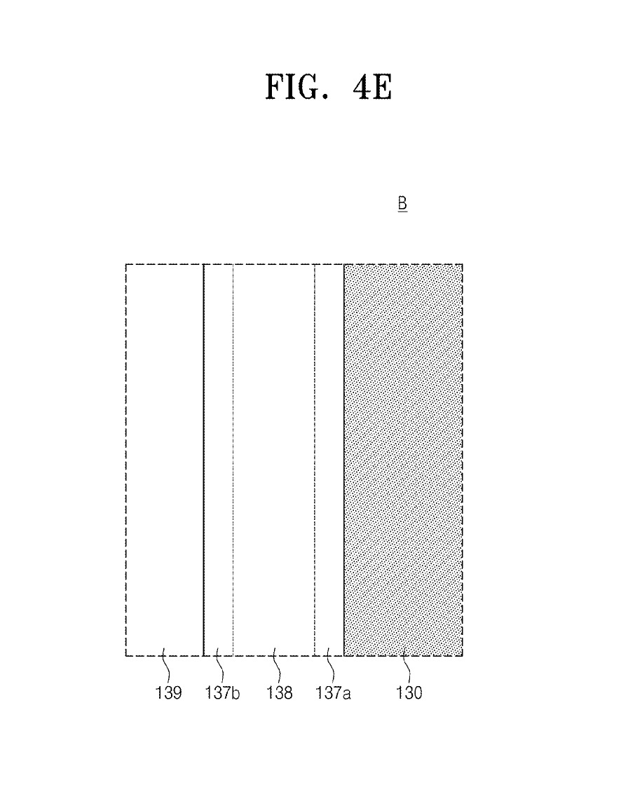

FIGS. 4A-4E illustrate embodiments of a memory device according to the inventive concepts.

The memory device includes a substrate 110. The substrate 110 may be a semiconductor substrate having a first conductivity type (e.g., a P-type). The semiconductor substrate may include at least one of a single-crystalline silicon layer, a silicon-on-insulator (SOI), a silicon layer formed on a silicon-germanium (SiGe) layer, a single-crystalline silicon layer formed on an insulating layer, and a poly-crystalline silicon layer formed on an insulating layer. The memory device includes gate stacks GL on the substrate 110. A buffer dielectric layer 122 may be provided between the substrate 110 and the gate stacks GL. The buffer dielectric layer 122 may include a silicon oxide layer.

The gate stacks GL may extend in the first direction D1. The gate stacks GL may be spaced apart from each other in the second direction D2 intersecting (e.g., perpendicular to) the first direction D1 by isolation trenches 141 extending in the first direction D 1. Each of the gate stacks GL may include insulating patterns 125 and gate electrodes between the insulating patterns 125. The gate electrodes may include first to sixth gate electrodes G1 to G6 that are sequentially stacked on the substrate 110. The insulating patterns 125 may include silicon oxide. The buffer dielectric layer 122 may be thinner than the insulating patterns 125. The gate electrodes G1 to G6 may include at least one of doped silicon, a metal (e.g., tungsten), a metal nitride, and a metal silicide. Six gate electrodes are illustrated in FIGS. 4A and 4C. However, inventive concepts are not limited thereto. In other embodiments, each gate stack GL includes five or less gate electrodes or seven or more gate electrodes.

Each of the gate stacks GL may have vertical holes 121 that extend through the gate electrodes G1 to G6 to the substrate 110. As illustrated in FIG. 4B, the vertical holes 121 of each of the gate stacks GL may be arranged in a zigzag form. However, the inventive concepts are not limited to this arrangement of the vertical holes 121.

Lower semiconductor patterns 132 may be provided in lower regions of the vertical holes 121. The lower semiconductor patterns 132 may contact the substrate 110. Top surfaces of the lower semiconductor patterns 132 may be higher than a top surface of the first gate electrode G1 corresponding to the lowermost one of the gate electrodes G1 to G6. Bottom surfaces of the lower semiconductor patterns 132 may be lower than the top surface of the substrate 110. In other words, lower portions of the lower semiconductor patterns 132 may be inserted into first recessed portions R1 of the substrate 110, respectively. The lower semiconductor patterns 132 may include silicon (Si) or silicon-germanium (SiGe). A gate insulating layer GOX may be disposed between the first gate electrode G1 and each of the lower semiconductor patterns 132. The gate insulating layer GOX may include a silicon oxide layer or a silicon-germanium oxide layer.

A plurality of active pillars 130 are respectively disposed in the vertical holes 121 and coupled to the gate electrodes G1 to G6. The active pillars 130 may be formed on the lower semiconductor patterns 132, respectively. The active pillars 130 may be electrically connected to the substrate 110 via the lower semiconductor patterns 132. Alternatively, the active pillars 130 are connected directly to the substrate 110, i.e., the lower semiconductor patterns 132 are optional.

Each of the active pillars 130 has a long axis extending upward from the substrate 110. In other words, the longitudinal axis of the active pillar 130 may extend in the third direction D3. First ends of the active pillars 130 may be connected to the lower semiconductor patterns 132, and second ends of the active pillars 130 may be connected to bit lines BL extending in the second direction D2. The active pillars 130 function as channels of metal-oxide-semiconductor (MOS) transistors. In this example, each of the active pillars 130 includes a first semiconductor pattern 134 and a second semiconductor pattern 136. The first semiconductor pattern 134 may be disposed along the sides of the vertical hole 121, and the second semiconductor pattern 136 may be disposed on a sidewall of the first semiconductor pattern 134. The second semiconductor pattern 136 may contact the top surface of the lower semiconductor pattern 132. A lower portion of the second semiconductor pattern 136 may extend into a recessed portion R2, i.e., a recess in the top, of the lower semiconductor pattern 132.

Accordingly, each of the active pillars 130 of this example includes a vertical portion lining sides of the vertical hole 121 and a bottom portion lining the bottom of the vertical hole 121. The vertical portion is constituted by the first semiconductor pattern 134 and a portion of the second semiconductor pattern 136, and the bottom portion is constituted by another portion of the second semiconductor pattern 136. The vertical portion of the active pillar 130 is thus thicker than its bottom portion (with the thickness of the vertical portion being a dimension of the side of the active pillar measured in direction D1 or D2 and the thickness of the bottom portion being a dimension of the bottom of the active pillar being measured in the direction D3). The bottom portion may contact the top surface of the lower semiconductor pattern 132. The bottom portion may extend into a recess in the top of the lower semiconductor pattern 132.

Each of the active pillars 130 may have a hollow cylindrical form. Thus, each of the active pillars 130 may have an inner hole 131. The inner hole 131 of each of the active pillars 130 may be filled with insulation, e.g., a filling insulation layer 139. The filling insulation layer 139 may be a silicon oxide layer. Conductive pads 128 may be provided on top ends of the active pillars 130, respectively. Portions of the active pillars 130, which are in contact with the conductive patterns 128, may be drain regions D.

A data storage element S is provided between each of the active pillars 130 and the gate electrodes G1 to G6. The data storage element S of this example includes a blocking dielectric BCL adjacent to the gate electrode, a tunnel dielectric TL adjacent to the active pillar 130, and a charge storage section CL (referred to hereinafter as a charge storage layer) layer disposed between the blocking dielectric BCL and the tunnel dielectric TL.

The blocking dielectric BCL may include a high-k dielectric layer (e.g., an aluminum oxide layer or a hafnium oxide layer). In some embodiments, the blocking dielectric BCL is a multi-layered structure consisting of a plurality of thin layers. For example, the blocking dielectric layer BCL may include a first blocking dielectric layer BCL1 and a second blocking dielectric layer BCL2. In this case, at least one of the first and second blocking dielectric layers BCL1 and BCL2 may include either an aluminum oxide layer or a hafnium oxide layer. At least a portion (e.g., the first blocking dielectric layer BCL1) of the blocking dielectric BCL may be interposed between the active pillar 130 and the insulating patterns 125. On the contrary, another portion (e.g., the second blocking dielectric layer BCL2) of the blocking dielectric BCL may be interposed between each of the gate electrodes G1 to G6 and the insulating patterns 125.

The charge storage layer CL may include a charge trap layer, or an insulating layer including conductive nano particles. The charge trap layer may include, for example, a silicon nitride layer. The charge storage layer CL may be interposed between the active pillar 130 and the insulating patterns 125, as in the illustrated embodiment. In other embodiments, at least a portion of the charge storage layer CL may be interposed between each of the gate electrodes G1 to G6 and the insulating patterns 125.

The tunnel dielectric TL may include a silicon oxide layer. An energy band gap of the tunnel dielectric TL may decrease and then increase in a direction away from the charge storage layer BCL. For example, the tunnel dielectric TL may include a first tunnel dielectric layer TL1, a second tunnel dielectric layer TL2, and a third tunnel dielectric layer TL3 which are sequentially stacked on the charge storage layer CL. An energy band gap of the third tunnel dielectric layer TL3 may be greater than that of the second tunnel dielectric layer TL2. The energy band gap of the third tunnel dielectric layer TL3 may be smaller than that of the first tunnel dielectric layer TL1. Each of the first to third tunnel dielectric layers TL1, TL2, and TL3 may include a silicon oxide layer. In addition, the tunnel dielectric layer TL may contain nitrogen of 5 atom % to 20 atom %. Nitrogen concentrations of the second and third tunnel dielectric layers TL2 and TL3 may be higher than that of the first tunnel dielectric layer TL1. The nitrogen concentration of the second tunnel dielectric layer TL2 may be higher than that of the third tunnel dielectric layer TL3. A nitrogen concentration of the first tunnel dielectric layer TL1 may be much lower than that of the charge storage layer CL.

The energy band gap of the first tunnel dielectric layer TL1 may be much greater than that of the charge storage layer CL. Thus, electrons, which are trapped in the charge storage layer CL in a programming operation, can be advantageously retained in the charge storage layer CL.

In addition, the number of dangling bonds generated at the interface between the tunnel dielectric TL and a silicon layer of the active pillar 130 is minimized because the interface is rich in nitrogen atoms.

The tunnel dielectric TL may further include a high-k dielectric layer (e.g., a hafnium oxide layer or an aluminum oxide layer). In some embodiments, the high-k dielectric layer of the tunnel dielectric TL is disposed between the second tunnel dielectric layer TL2 and the third tunnel dielectric layer TL3.

A current may flow in the active pillar 130 adjacent to the filling insulation layer 139. In this case, current characteristics may depend on characteristics of the interface between the active pillar 130 and the filling insulation layer 139. The influence of the interface of the active pillar 130 and the filling insulation layer 139 on the current flowing through the active pillar 130 is accounted for according to the inventive concepts in way which will be described hereinafter.

According to an embodiment, a fixed charge layer 138 is interposed between the active pillar 130 and the filling insulation layer 139. The fixed charge layer 138 has negative fixed charges, for example. In this case, the fixed charge layer 138 may include an aluminum oxide layer, an aluminum nitride layer, an aluminum oxynitride layer or a composite layer of such materials. The current may be kept far away from the interface of the active pillar 130 and the fixed charge layer 138 by the negative fixed charges and hence, may flow through the active pillar along a path remote from the filling insulation layer 139. As a result, the memory device may have an improved retention characteristic. In addition, the negative fixed charges may increase a critical voltage of the vertical channel (e.g., a threshold voltage).

The critical voltage may be greatly varied by the negative fixed charges, however. To solve this potential problem, a first insulating buffer 137a (referred to hereinafter as first insulating buffer “layer” 137a) may be provided between the fixed charge layer 138 and the active pillar 130. The first buffer insulating layer 137a may include a material different from any material of the fixed charge layer 138. The first buffer insulating layer 137a may include a silicon oxide layer, a silicon nitride layer or a composite of silicon oxide and silicon nitride. The first buffer insulating layer 137a may control or reduce the critical voltage such that variations in the voltage are not excessive. In addition, the first buffer insulating layer 137a may relieve stress between the fixed charge layer 138 and the active pillar 130. In the case in which the first buffer insulating layer 137a includes a silicon nitride layer, the silicon nitride layer can prevent oxygen from diffusing from the fixed charge layer 138 to the active pillar 130.

In addition, a second insulating buffer 137b (referred to hereinafter as second insulating buffer “layer” 137b) may be provided between the fixed charge layer 138 and the filling insulation layer 139. The second buffer insulating layer 137b may include a material different from any of those of the fixed charge layer 139 and the filling insulation layer 138. The second buffer insulating layer 137b may include a silicon oxide layer or a silicon nitride layer. The second buffer insulating layer 137b may include a material having an etch selectivity with respect to the filling insulation layer 139. For example, the second buffer insulating layer 137b may include a material (e.g., a silicon oxide layer) whose wet etch rate is greater than that of the filling insulation layer 139. The second buffer insulating layer 137b may relieve stress between the filling insulation layer 139 and the fixed charge layer 138.

Alternatively, the fixed charge layer 138 may have positive fixed charges. In this case, the fixed charge layer 138 may include a hafnium oxide layer, a silicon nitride layer, a boron nitride layer, a carbon-doped silicon (SiC) layer, a boron-doped silicon layer or a composite layer of two or more of these materials. The positive fixed charges may reduce the critical voltage of the channel.

In this case, the first buffer insulating layer 137a between the fixed charge layer 138 and the active pillar 130 may control the critical voltage such that any variations in the critical voltage are not excessive and may relieve the stress between the fixed charge layer 138 and the active pillar 130. In addition, the first buffer insulating layer 137a may prevent an element of material of the fixed charge layer 138 from diffusing to the active pillar 130. For example, silicon nitride of the first buffer insulating layer 137a may prevent boron of a boron or carbon of the fixed charge layer 138 from diffusing to the active pillar 130.

In addition, the second buffer insulating layer 137b may be provided between the fixed charge layer 138 and the filling insulation layer 139.

According to other embodiments, the material of the first and second semiconductor patterns 134 and 136 may be a factor controlling the critical voltage in the device. In one embodiment, each of the first and second semiconductor patterns 134 and 136 includes a silicon layer doped with impurities (ions) of the first conductivity type but the dopant concentration of (i.e., concentration of the ions of the dopant in) the first semiconductor pattern 134 is different from that of the second semiconductor pattern 136. For example, the dopant concentration of the first semiconductor pattern 134 may be lower than that of the second semiconductor pattern 136. Thus, the current may flow through a portion (i.e., the first semiconductor pattern 134) of the active pillar 130 which is remote from the interface between the active pillar 130 and the filling insulation layer 139 and is adjacent to the tunnel dielectric layer TL. As a result, the above-mentioned influence of the interface on the current may be reduced and the retention characteristic of the memory device may be improved. In addition, the critical voltage of the channel may be reduced. In another embodiment, the first semiconductor pattern 134 is of material different from of that the second semiconductor pattern 136. For example, the first semiconductor pattern 134 and the second semiconductor pattern 136 are of a silicon-germanium layer and a silicon layer, respectively. Alternatively, each of the first and second semiconductor patterns 134 and 136 may include a silicon layer containing germanium, in which case the germanium concentration of the first semiconductor pattern 134 is different from that of the second semiconductor pattern 136. For example, the germanium concentration of the first semiconductor pattern 134 is higher than that of the second semiconductor pattern 136. Thus, the current may flow through a portion (i.e., the first semiconductor pattern 134) of the active pillar 130 which is far from the interface between the active pillar 130 and the filling insulation layer 139 and is adjacent to the tunnel dielectric layer TL. In other words, the aforementioned influence of the interface may be reduced and the retention characteristic of the memory device may be improved.

According to still other embodiments, the filling insulation layer 139 may contain impurities (i.e., ions of a dopant). For example, the filling insulation layer 139 may include borosilicate glass (BSG), phosphosilicate glass (PSG), or borophosphosilicate glass (BPSG). The dopant in the filling insulation layer 139 may induce an effect similar to that of the above-described fixed charge layer 138.

Also, the aforementioned techniques may be combined in various forms in accordance with the present inventive concepts.

Referring back to FIG. 3, a plurality of cell strings CSTR of a flash memory device may be provided between bit lines BL and common source lines CSL. Each of the cell strings may include the string selection transistor SST, the ground selection transistor GST, and the plurality of memory cells MCT. The selection transistors SST and GST and the plurality of memory cells MCT may be provided on one active pillar 130. The first gate electrode G1 may be the ground selection line GSL of the ground selection transistor GST. The second to fifth gate electrodes G2 to G5 may be the word lines WL1 to WLn of the memory cells MCT. The sixth gate electrode G6 may be the string selection line SSL of the string selection transistor SST.

Each of the isolation trenches 141 extending in the first direction may be provided between adjacent ones of the gate stacks GL. The isolation trenches 141 and the gate stacks GL may be alternatively arranged in the second direction D2. Common source regions 142 may be provided in the substrate 110 exposed through each of the isolation trenches 141. The common source regions 142 may be spaced apart from each other and may extend along the first direction D1 in the substrate 110. The common source regions 142 may have a second conductivity type (e.g., an N-type) different from the first conductivity type. A device isolation pattern 145 may be disposed on each of the common source regions 142 to fill each of the isolation trenches 141. The device isolation pattern 145 may include a silicon oxide layer. A common contact layer (not shown) may be provided between the device isolation pattern 145 and the common source region 142. The common contact layer (not shown) may be a metal-semiconductor compound layer. For example, the common contact layer (not shown) may be a metal silicide layer. An insulating spacer 143 may be provided on a side of the gate stack SL. The insulating spacer 143 may be provided between the side of the gate stack ST and the device isolation pattern 145. The insulating spacer 143 may include a silicon oxide layer, a silicon oxynitride layer, a silicon nitride layer, and/or an aluminum oxide layer.

Strapping plugs 140 may extend vertically through the device isolation patterns 145 and be electrically connected to the common source regions 142. The strapping plugs 140 connected to each of the common source regions 142 may be arranged along the first direction D 1. A barrier layer 148 may be provided between the device isolation pattern 145 and each of the strapping plugs 140. The strapping plugs 140 may include a metal (e.g., tungsten, copper, or aluminum). The barrier layer 148 may include a conductive metal nitride (e.g., titanium nitride or tantalum nitride). The common contact layer (not shown) may be provided between the strapping line 140 and the common source regions 142.

A strapping line 160 may be provided on the device isolation pattern 145 as extending in the first direction D1. The strapping line 160 may be disposed over each of the common source regions 142. The strapping line 160 may be electrically connected to the strapping plugs 140 through first contacts 162. The strapping line 160 and the first contacts 162 may include at least one of a metal (e.g., tungsten, copper, or aluminum), a conductive metal nitride (e.g., titanium nitride or tantalum nitride), and a transition metal (e.g., titanium or tantalum).

Bit lines BL may be provided on the strapping line 160 as extending in the second direction D2. The bit lines BL may be electrically connected to the active pillars 130 through second contacts 164. The bit lines BL and the second contacts 164 may include at least one of a metal (e.g., tungsten, copper, or aluminum), a conductive metal nitride (e.g., titanium nitride or tantalum nitride), and a transition metal (e.g., titanium or tantalum).

A common source line CSL may be provided on the strapping line 160 as extending in the second direction D2. The common source line CSL may be electrically connected to the strapping lines 160 through third contacts 166. The common source line CSL and the third contacts 166 may include at least one of a metal (e.g., tungsten, copper, or aluminum), a conductive metal nitride (e.g., titanium nitride or tantalum nitride), and a transition metal (e.g., titanium or tantalum).

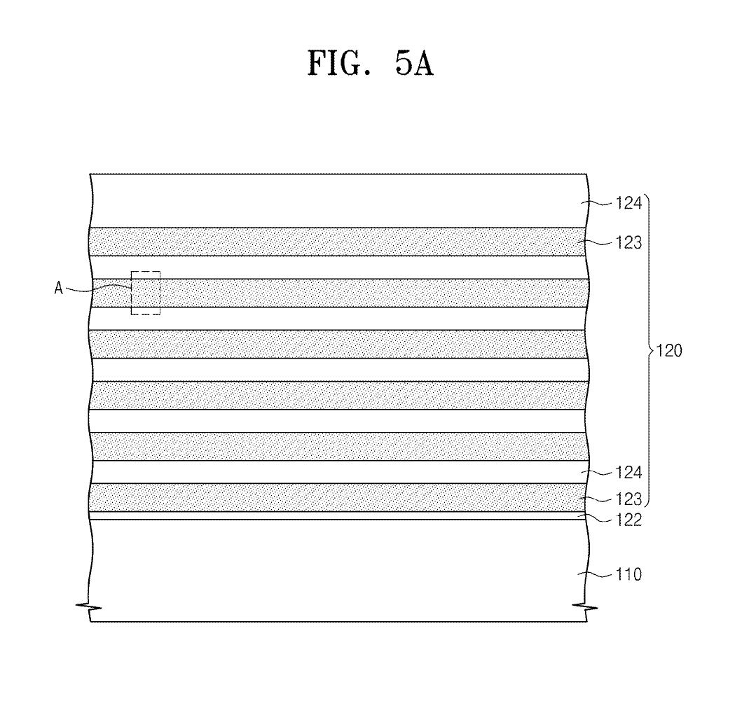

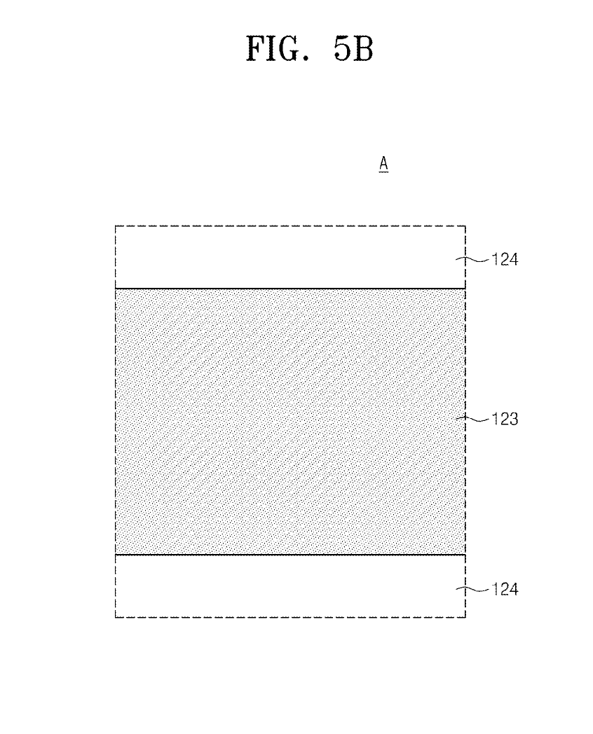

A method of manufacturing a memory device according to the inventive concepts will be described hereinafter with reference to FIGS. 5A to 12B.

Referring to FIGS. 5A and 5B, a substrate 110 may be provided. The substrate 110 may be a semiconductor substrate having a first conductivity type (e.g., a P-type). The semiconductor substrate may include at least one of a single-crystalline silicon layer, silicon-on-insulator (SOD, a silicon layer formed on a silicon-germanium (SiGe) layer, a single-crystalline silicon layer formed on an insulating layer, and a poly-crystalline silicon layer formed on an insulating layer.

A buffer dielectric layer 122 may be formed on the substrate 110. The buffer dielectric layer 122 may be, for example, a silicon oxide layer. The buffer dielectric layer 122 may be formed by, for example, a thermal oxidation process. A preliminary gate stack 120 may be formed on the buffer dielectric layer 122. The preliminary gate stack 120 may include sacrificial layers 123 and insulating layers 124 that are alternately stacked on the buffer dielectric layer 122. A thickness of the uppermost one of the insulating layers 124 may be greater than those of others of the insulating layers 124. Each of the insulating layers 124 may be, for example, a silicon oxide layer. The sacrificial layers 123 may include a material having a wet etch selectivity with respect to the buffer dielectric layer 122 and the insulating layers 124. For example, each of the sacrificial layers 123 may be a silicon nitride layer, a silicon oxynitride layer, a poly-crystalline silicon layer, or a poly-crystalline silicon-germanium layer. Each of the sacrificial layers 123 and the insulating layers 124 may be formed by, for example, a chemical vapor deposition (CVD) method.

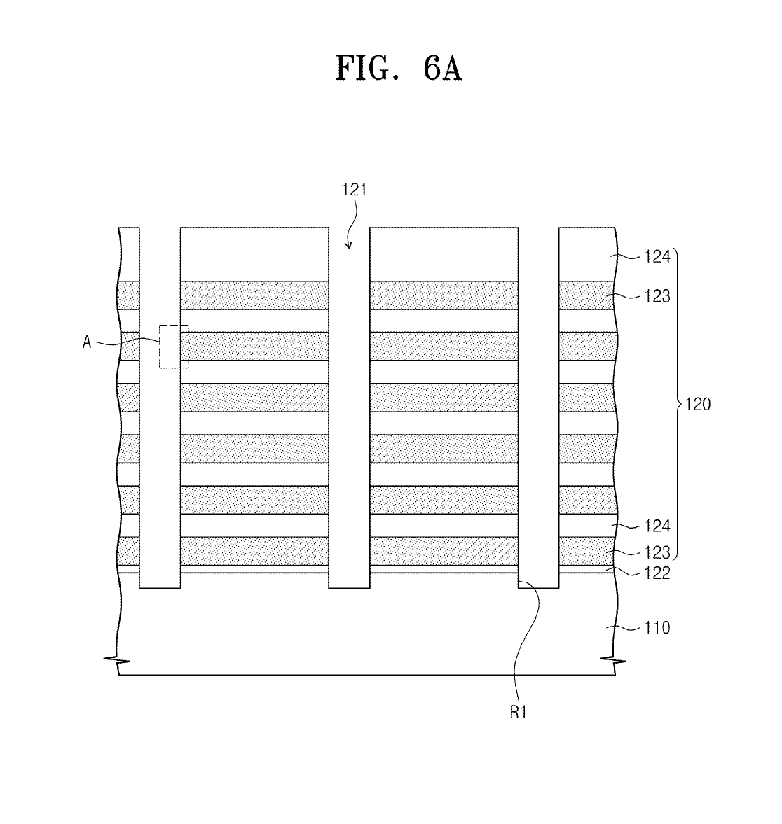

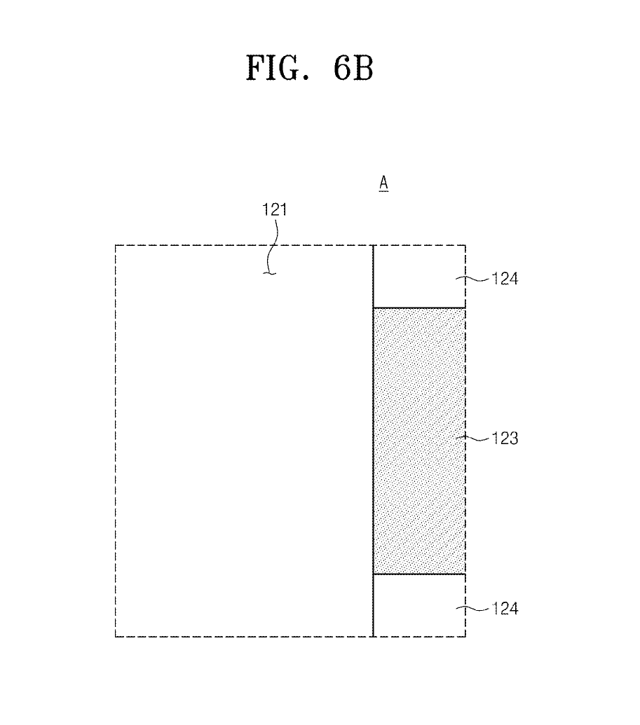

Referring to FIGS. 6A and 6B, vertical holes 121 may be formed through the preliminary gate stack 120. The vertical holes 121 may expose the substrate 110. The process of forming the vertical holes 121 may include an anisotropic etching process. As a result of the process of forming the vertical holes 121, first recesses portions R1 may be formed in the substrate 110.

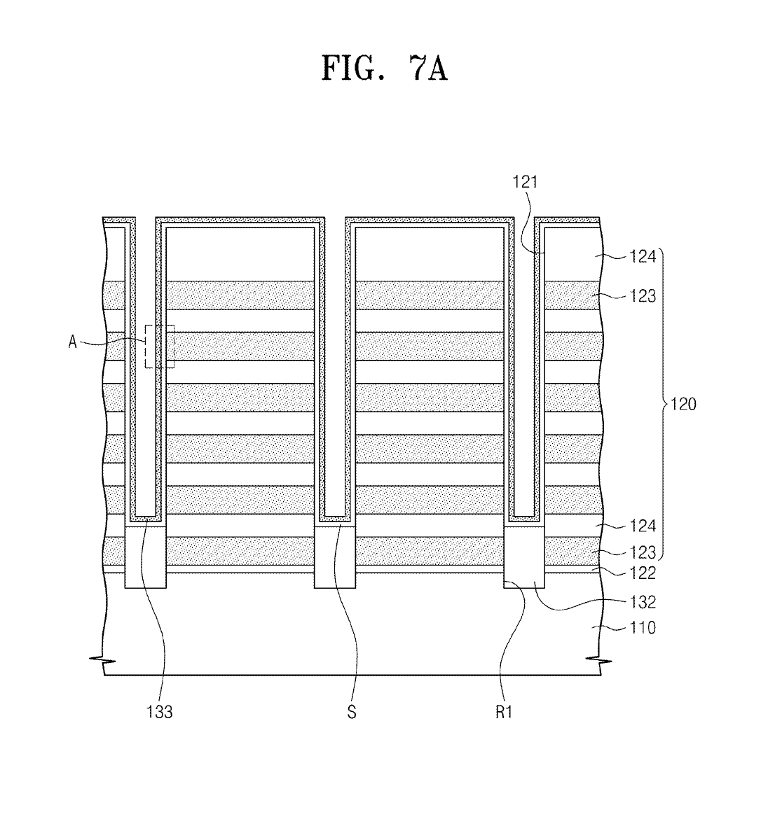

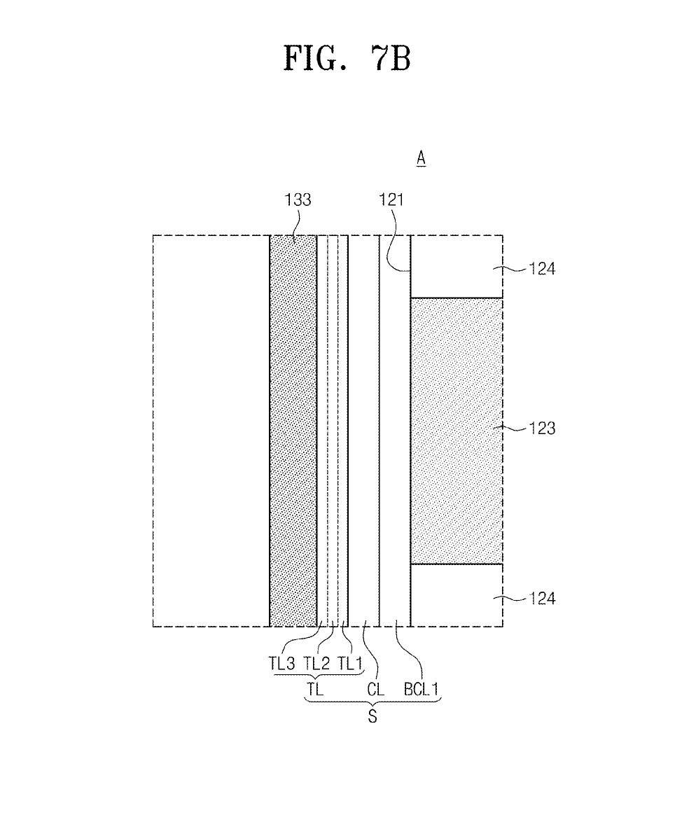

Referring to FIGS. 7A and 7B, a lower semiconductor pattern 132 may be formed in a lower region of each of the vertical holes 121. The lower semiconductor pattern 132 may be formed by a selective epitaxial growth (SEG) process. The lower semiconductor pattern 132 may fill the first recess R1 and may protrude upwardly beyond the level of a top surface of the substrate 110. A top surface of the lower semiconductor pattern 132 may be disposed at a level between a top surface of a lowermost sacrificial layer and a top surface of a next-lowermost sacrificial layer. The lower semiconductor pattern 132 may include silicon or silicon-germanium.

A first blocking dielectric layer BCL1 may be formed in the vertical holes 121. The first blocking dielectric layer BCL1 may be formed by an atomic layer deposition (ALD) method. The first blocking dielectric layer BCL1 may include a high-k dielectric layer. The first blocking dielectric layer BCL1 may be a multi-layered composite of a plurality of thin layers. For example, the first blocking dielectric layer BCL1 may include a hafnium oxide layer, an aluminum oxide layer, and/or a silicon oxide layer. The order in which the hafnium oxide layer, the aluminum oxide layer, and the silicon oxide layer are formed and stacked on the other may vary from case to case.

A charge storage layer CL is formed. The charge storage layer CL may be formed on the first blocking dielectric layer BCL1. The charge storage layer CL may be formed by an ALD method. The charge storage layer CL may include a charge trap layer or an insulating layer including conductive nano particles. The charge trap layer may include, for example, a silicon nitride layer.

A tunnel dielectric TL is formed on the charge storage layer CL. The tunnel dielectric TL may include a first tunnel dielectric layer TL1, a second tunnel dielectric layer TL2, and a third tunnel dielectric layer TL3. A process of forming the tunnel dielectric TL will be described in detail.

First, a first preliminary tunnel dielectric layer (not shown), a second preliminary tunnel dielectric layer (not shown), and a third preliminary tunnel dielectric layer (not shown) may be sequentially formed on the charge storage layer CL. Energy band gaps of the preliminary tunnel dielectric layers may decrease in a direction away from the charge storage layer. Each of the preliminary tunnel dielectric layers may include a silicon oxide layer containing nitrogen. Nitrogen concentrations of the first, second and third preliminary tunnel dielectric layers may sequentially increase. In other words, the nitrogen concentration of the third preliminary tunnel dielectric layer may be higher than that of the second preliminary tunnel dielectric layer, and the nitrogen concentration of the second preliminary tunnel dielectric layer may be higher than that of the first preliminary tunnel dielectric layer.

Subsequently, a thermal treatment process may be performed. The thermal treatment process may be an oxidation treatment process. For example, the thermal treatment process may be performed in an oxidation atmosphere. The thermal treatment process may be performed under, for example, an N₂O or NO gas atmosphere. For example, the thermal treatment process may be a radical oxidation process or a plasma oxidation process. A process temperature of the thermal treatment process may be in a range of 750° C. to 950° C. During the thermal treatment process, the amount of oxygen supplied to the third preliminary tunnel dielectric layer may be more than the amount of the oxygen supplied to the second preliminary tunnel dielectric layer.

As a result, the first, second, and third tunnel dielectric layer TL1, TL2, and TL3 may be formed one on the other in the foregoing order on the charge storage layer CL. By the thermal treatment process described above, the nitrogen concentration of the first tunnel dielectric layer TL1 may be lower than those of the second and third tunnel dielectric layers TL2 and TL3, and the nitrogen concentration of the third tunnel dielectric layer TL3 may be lower than that of the second tunnel dielectric layer TL2. Accordingly, an energy band gap of the tunnel dielectric layer TL may decrease and then increase in a direction away from the charge storage layer CL. In other words, an energy band gap of the third tunnel dielectric layer TL3 may be greater than that of the second tunnel dielectric layer TL2 and may be smaller than that of the first tunnel dielectric layer TL1.

Due to the above mentioned processes, the nitrogen concentration of the first tunnel dielectric layer TL1 adjacent to the charge storage layer CL may be much lower than that of the charge storage layer CL. The energy band gap of the first tunnel dielectric layer TL1 may be much greater than that of the charge storage layer CL. Thus, electrons trapped in the charge storage layer CL in a programming operation may be advantageously retained in the charge storage layer CL.

In addition, an interface between the tunnel dielectric layer TL and an active pillar (see 130 of FIG. 4C) is rich in nitrogen atoms. Therefore, a minimal number of dangling bonds are created at the interface of the tunnel dielectric layer TL and the active pillar 130. An interface characteristic between the tunnel dielectric layer TL and the active pillar 130 may be improved by a reverse-type formation process of the tunnel dielectric layer according to the inventive concepts. In other words, retention and endurance characteristics of the tunnel dielectric layer TL may be improved by the reverse-type formation process of the tunnel dielectric layer according to the inventive concepts. The thermal treatment process described above may cure defects of the charge storage layer CL.

The first blocking dielectric layer BCL1, the charge storage layer CL, and the tunnel dielectric TL may extend onto the top surfaces of the lower semiconductor pattern 132 and a top surface of the preliminary gate stack 120.

Active pillars 130 are formed on the tunnel dielectric layer TL in the vertical holes 121. A method of forming the active pillars 130 will be described in more detail.

First, a first semiconductor layer 133 may be formed on the tunnel dielectric TL. The first semiconductor layer 133 may extend onto the top surfaces of the lower semiconductor pattern 132 and the preliminary gate stack 120.

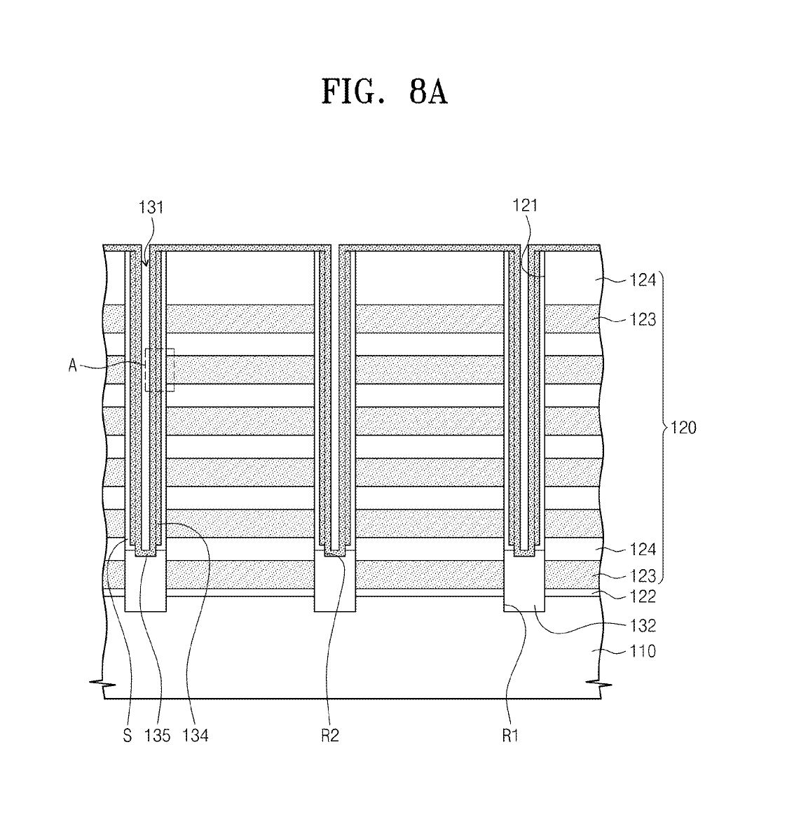

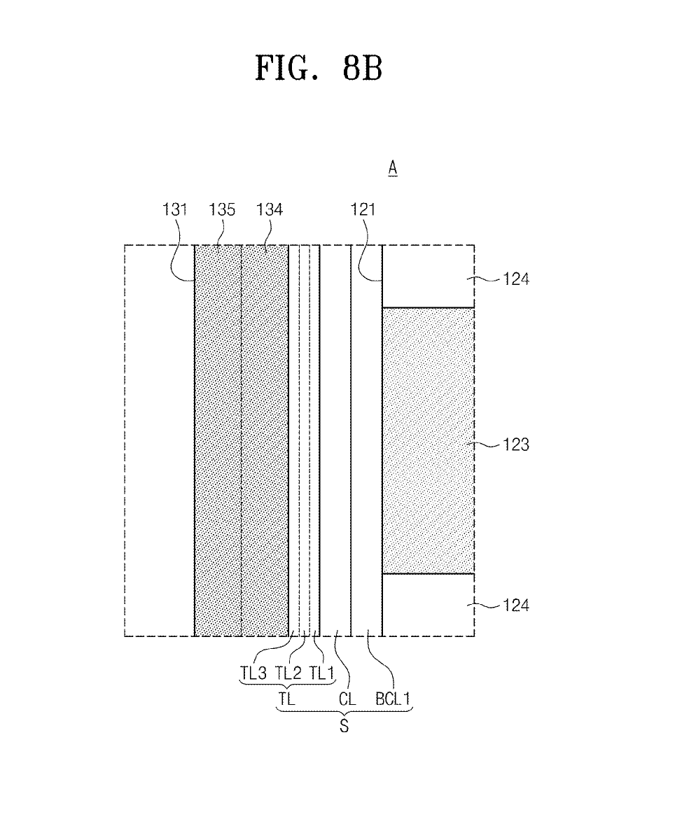

Referring to FIGS. 8A and 8B, the first semiconductor layer 133 may be anisotropic ally etched to form a first semiconductor pattern 134 along the side of each of the vertical holes 131. The first semiconductor pattern 134 may have the form of a sidewall spacer. The first semiconductor pattern 134 may expose the lower semiconductor pattern 132. A second recess, constituting recessed portion R2, may be formed in the top surface of the lower semiconductor pattern 132 by the anisotropic etching process.

A second semiconductor layer 135 may be formed on the first semiconductor pattern 134. The second semiconductor layer 135 may extend along the second recessed portion R2 and the top surface of the preliminary gate stack 120. A lower portion of the second semiconductor layer 135 disposed in the vertical hole 121 may extend into the second recessed portion R2 of the lower semiconductor pattern 132.

Each of the first and second semiconductor layers 133 and 135 may be formed by a CVD method or an ALD method. In one embodiment, each of the first and second semiconductor layers 133 and 135 is formed of a silicon layer doped with ions (impurities) of the first conductivity type. In this case, the dopant (ion) concentration of the first semiconductor layer 133 may be different from that of the second semiconductor layer 135. For example, the dopant concentration of the first semiconductor layer 133 may be lower than that of the first semiconductor layer 135. In another embodiment, the first semiconductor layer 133 is formed of material different from the second semiconductor layer 135. For example, the first semiconductor layer 133 and the second semiconductor layer 135 may be formed as a silicon-germanium layer and a silicon layer, respectively. Alternatively, each of the first and second semiconductor layers 133 and 135 may be formed of a silicon layer containing germanium with the germanium concentration of the first semiconductor layer 133 being higher than that of the second semiconductor layer 135.

The second semiconductor layer 135 may be formed to partially fill the vertical holes 121 such that inner holes 131 defined by inner sidewall surfaces of the second semiconductor layer 135 may be formed in the vertical holes 121, respectively.

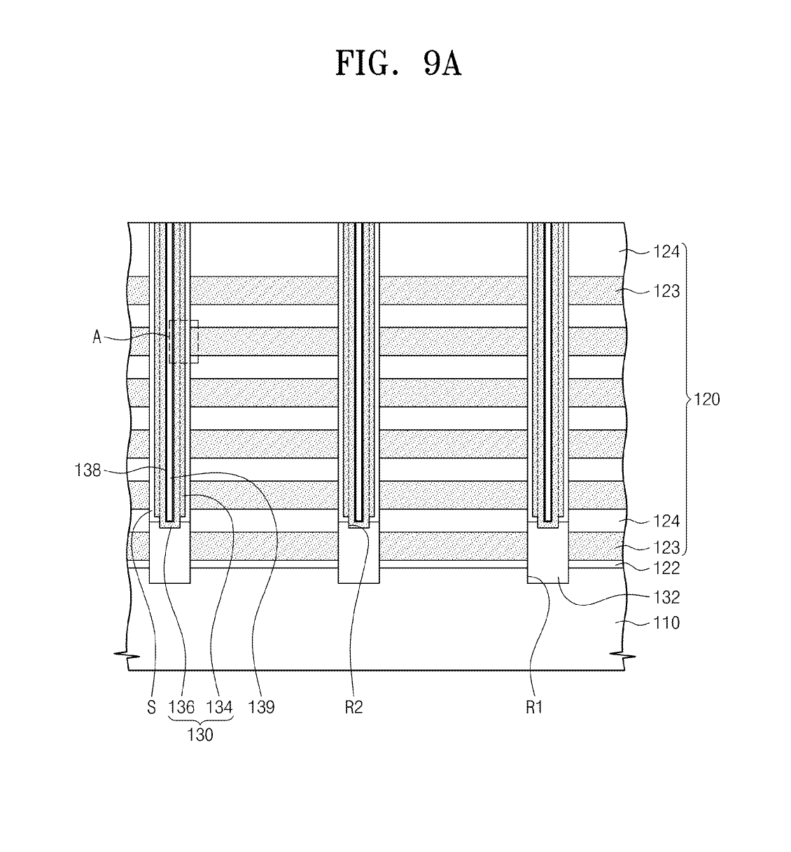

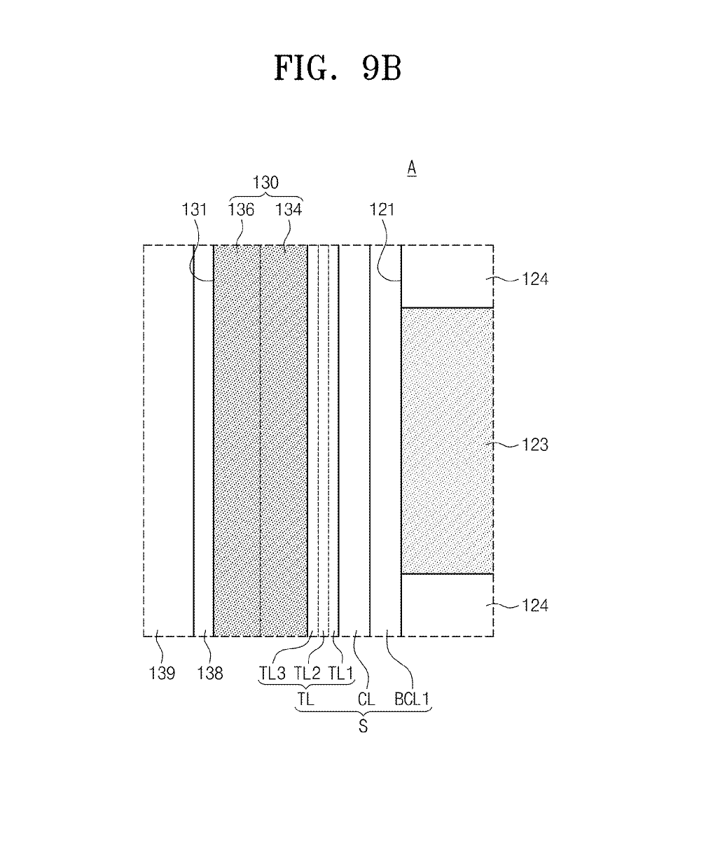

Referring to FIGS. 9A, 9B, and 4E, a first buffer insulating layer 137a may be formed on the second semiconductor layer 135. The first buffer insulating layer 137a may include a silicon oxide layer or a silicon nitride layer or may be a composite layer of silicon oxide and silicon nitride.

A fixed charge layer 138 is formed. The fixed charge layer may be formed on the first buffer insulating layer 137a. In one embodiment, the fixed charge layer 138 has negative fixed charges. In this case, the fixed charge layer 138 may include an aluminum oxide layer, an aluminum nitride layer, or an aluminum oxynitride layer. In another embodiment, the fixed charge layer 138 has positive fixed charges. In this case, the fixed charge layer 138 may include a hafnium oxide layer, a silicon nitride layer, a boron nitride layer, a carbon-doped silicon (SiC) layer, or a boron-doped silicon layer or a composite of two or more of these materials.

A second buffer insulating layer 137b may be additionally formed on the fixed charge layer 138. The second buffer insulating layer 137b may be formed of material different from that of the fixed charge layer 138. The second buffer insulating layer 137b may include a silicon oxide layer or a silicon nitride layer.

A filling insulation layer 139 is formed. The filling insulation layer may be formed on the second buffer insulating layer 137b to fill the inner holes 131. The filling insulation layer 139 may be formed of a silicon oxide layer. The filling insulation layer 139 may contain dopant. For example, the filling insulation layer 139 may include BSG, PSG, or BPSG.

The second buffer insulating layer 137b may be formed of material having an etch selectivity with respect to the filling insulation layer 139. For example, the second buffer insulating layer 137b may be formed of material (e.g., silicon oxide) whose wet etch rate is higher than that of the filling insulation layer 139. The second buffer insulating layer 137b may relieve the stress which would otherwise occur between the filling insulation layer 139 and the fixed charge layer 138. In addition, the second buffer insulating layer 137b may prevent the dopant (impurity ions) contained in the filling insulation layer 139 from diffusing to the active pillar 130.

The filling insulation layer 139, the fixed charge layer 138, the buffer insulating layers 137a and 137b, and the second semiconductor layer 135 may be planarized to expose the uppermost insulating layer of the preliminary gate stack 120. A second semiconductor pattern 136 may be formed from the second semiconductor layer 135 as a result of the planarization process. Also, as a result, a cylindrical active pillar 130 may be formed in each of the vertical holes 121 as filled with the filling insulation layer 139. In this example, the active pillar 130 is formed of the first semiconductor pattern 134 and the second semiconductor pattern 136 disposed on the first semiconductor pattern 134.

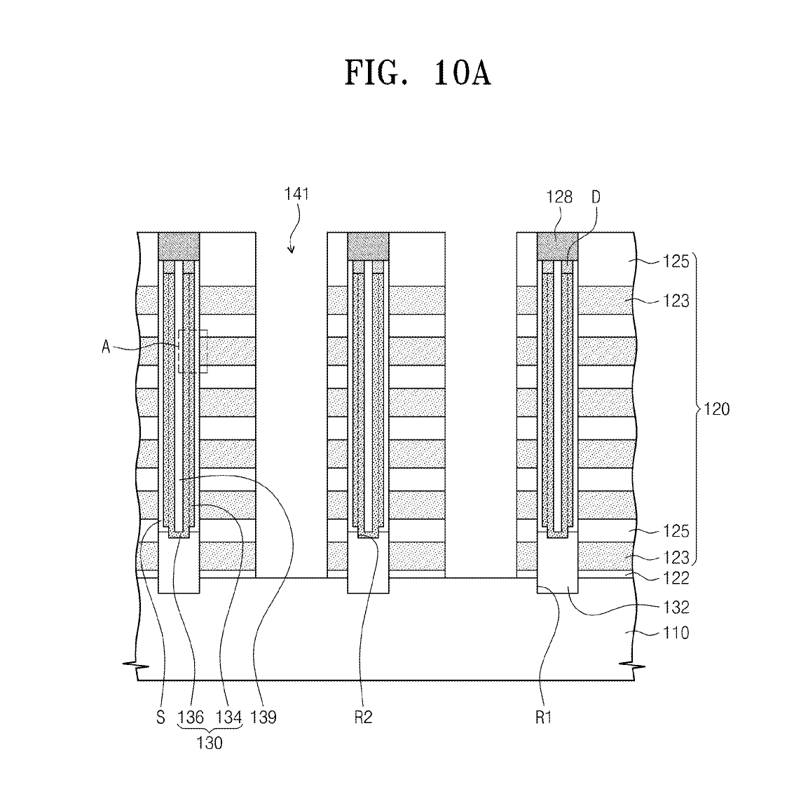

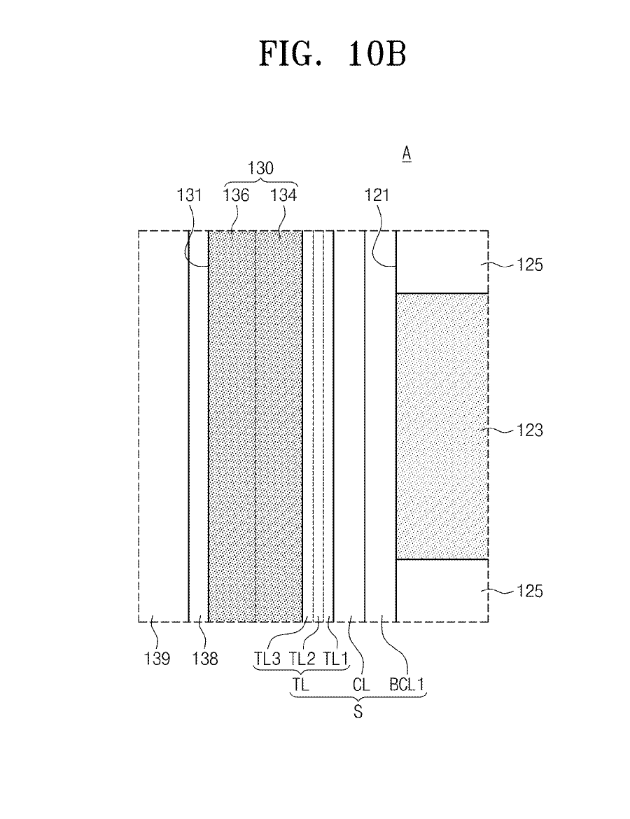

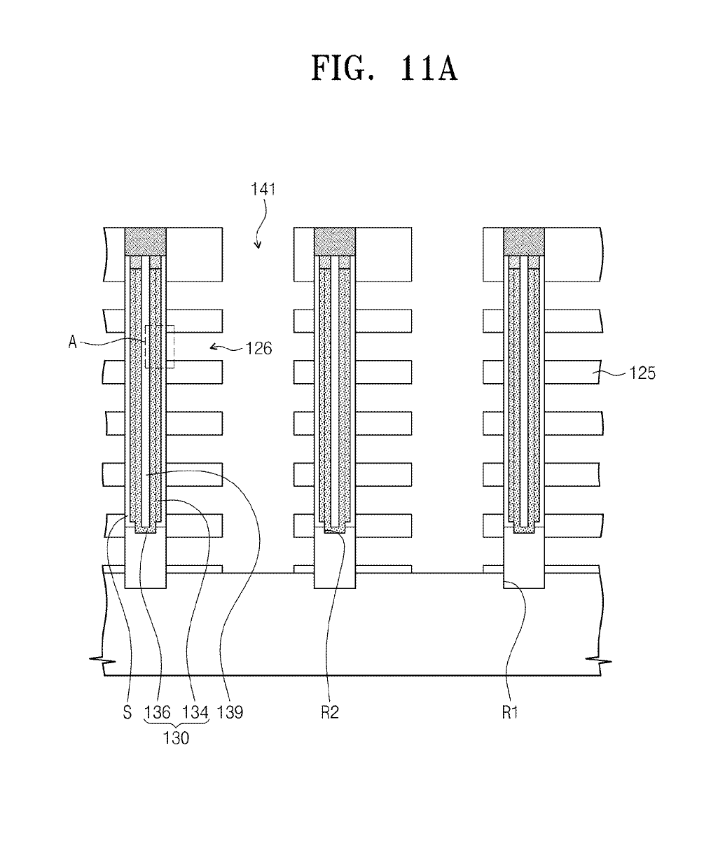

Referring to FIGS. 10A and 10B, upper parts of the active pillars 130 may be removed such that top surfaces of the recessed active pillars 130 are disposed at a level lower than that of a top surface of the uppermost insulating layer of the preliminary gate stack 120. Conductive patterns 128 may be formed on the top surfaces of the active pillars 130 in the vertical holes 121, respectively. The conductive patterns 128 may include doped poly-crystalline silicon or a metal. Dopant (ions) of a second conductivity type may be implanted into the conductive patterns 128 and upper portions of the active pillars 130 to form drain regions D. The second conductivity type may be, for example, an N-type.

The insulating layers 124, the sacrificial layers 123, and the buffer dielectric layer 122 may be successively patterned to form isolation trenches 141 that are spaced apart from each other and extend in the first direction D1. The isolation trenches 141 may expose the substrate 110. The patterned insulating layers 124 are shown and referred to merely as insulating patterns 125.

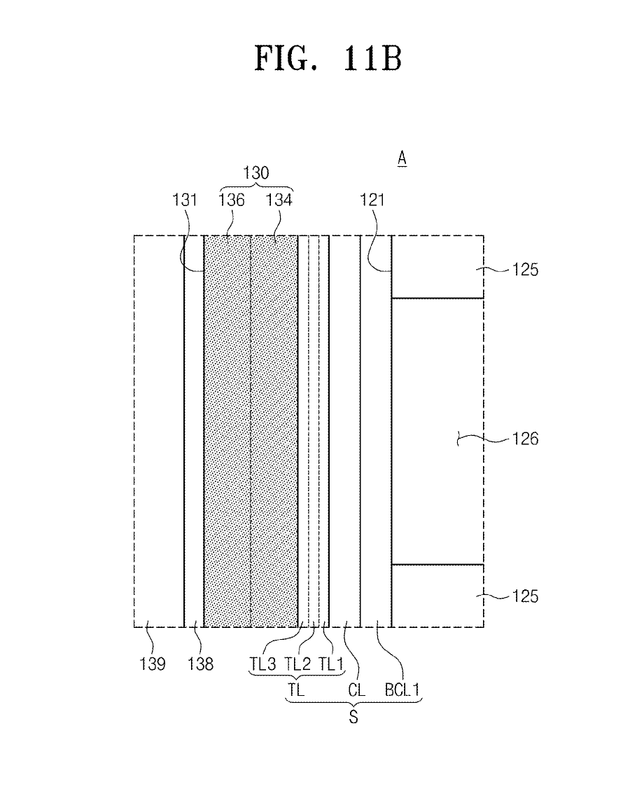

Referring to FIGS. 11A and 11B, the sacrificial layers 123 exposed by the isolation trenches 141 may be selectively removed to form gate regions 126. That is, the gate regions 126 may correspond to empty regions formed by removing the sacrificial layers 123 and may be defined by the active pillars 130 and the insulating patterns 125. If each of the sacrificial layers 123 includes a silicon nitride layer or a silicon oxynitride layer, the process of removing the sacrificial layers 123 may be performed using an etching solution including phosphoric acid. Portions of the first blocking dielectric layer BCL1 and a portion of the lower semiconductor pattern 132 may be exposed through the gate regions 126.

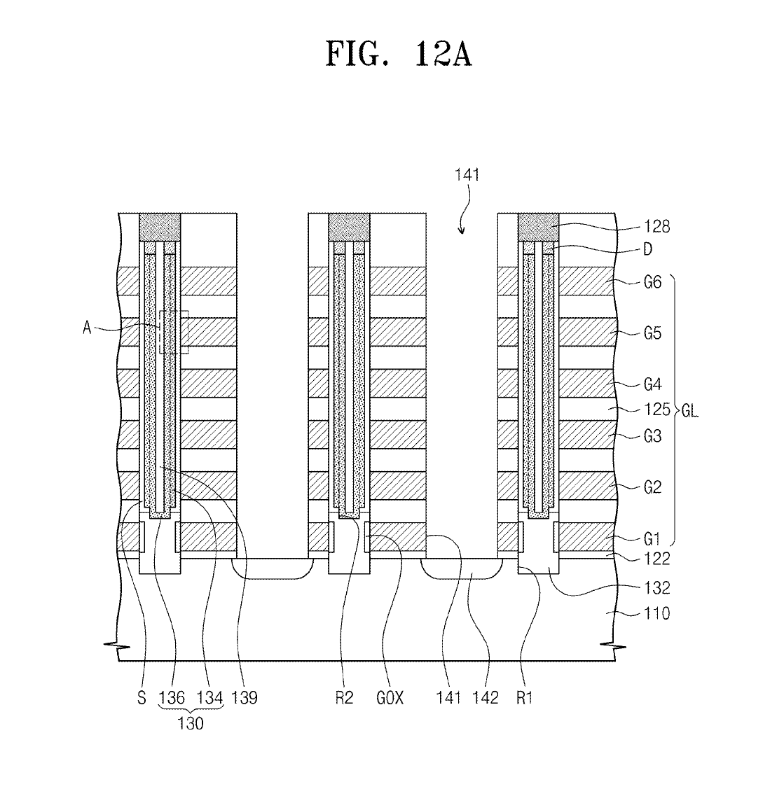

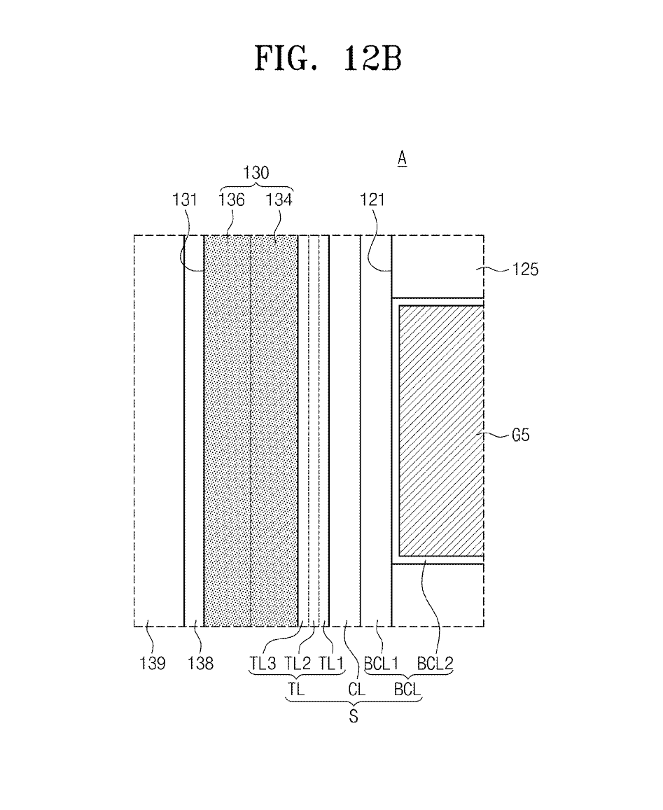

Referring to FIGS. 12A and 12B, the lower semiconductor pattern 132 exposed by the gate region 126 may be thermally oxidized to form a gate oxide layer GOX (e.g., a silicon oxide layer or a silicon-germanium oxide layer). Subsequently, a second blocking dielectric layer BCL2 may be formed on the insulating patterns 125 and the first blocking dielectric layer BCL1 which are exposed by the gate regions 126. The second blocking dielectric layer BCL2 may include a silicon oxide or a high-k dielectric layer (e.g., an aluminum oxide layer or a hafnium oxide layer) or may be a composite of these materials. In this example, therefore, the first blocking dielectric layer BCL1 and the second blocking dielectric layer BCL2 constitute a blocking dielectric BCL. Therefore, blocking dielectric BCL may include a silicon oxide layer, an aluminum oxide layer and/or a hafnium oxide layer. The blocking dielectric BCL may be formed by an ALD method.

A conductive layer (not shown) may be formed in the gate regions 126 through the isolation trenches 141. The conductive layer may be formed of at least one of a doped poly-crystalline silicon layer, a metal layer (e.g., a tungsten layer), and a metal nitride layer. For example, the conductive layer includes a metal nitride layer and a metal layer disposed on the metal nitride layer. The conductive layer may be formed by an ALD method.

Next, the conductive layer outside the gate regions 126 (e.g., in the isolation trenches 141) may be removed to form gate electrodes G1 to G6 in the gate regions 126. The conductive layer formed in the isolation trenches 141 may be removed such that the substrate 110 may be exposed.

Referring again to FIGS. 4A to 4E, dopant of the second conductivity type may be heavily implanted into the exposed substrate 110 to form common source regions 142.

Insulating spacers 143 may be formed along sides of the isolation trenches 141. For example, a silicon oxide layer or silicon nitride layer may be conformally formed, and the silicon oxide layer or silicon nitride layer may be anisotropically etched to form the insulating spacers 143.

A device isolation pattern 145 may be formed to fill each of the isolation trenches 141. The device isolation pattern 145 may extend in the first direction D1. The device isolation pattern 145 may include a silicon oxide layer. A top surface of the device isolation pattern 145 may be disposed at the same level as top surfaces of the uppermost insulating patterns 125.

Strapping plugs 140 may be formed in the device isolation pattern 145. A barrier layer 148 may be formed on the device isolation pattern 145 so as to be interposed between the device isolation pattern 145 and each of the strapping plugs 140. The strapping plugs 140 may include a metal (e.g., tungsten, copper, or aluminum). The barrier layer 148 may include a conductive metal nitride (e.g., titanium nitride or tantalum nitride). The strapping plugs 140 may be electrically connected to the common source regions 142 through common contact layers (not shown).

First contacts 162 may be formed to be connected to the strapping plugs 140. A strapping line 160 may be provided on the first contacts 162. The strapping line 160 may be connected to a group of the first contacts 162 connected to one common source region 142. The strapping line 160 may extend in the first direction D1. The strapping line 160 may be electrically connected to the strapping plugs 140 through the first contacts 162. The strapping line 160 and the first contacts 162 may be formed of at least one of a metal (e.g., tungsten, copper, or aluminum), a conductive metal nitride (e.g., titanium nitride or tantalum nitride), and a transition metal (e.g., titanium or tantalum).

Second contacts 164 may be formed to be connected to the active pillars 130. Bit lines BL may be formed on the second contacts 164 so as to be connected to the second contacts 164. The bit line BL may extend in the second direction D2. The bit lines BL may be electrically connected to the active pillars 130 through the second contacts 164. The bit lines BL and the second contacts 164 may be formed of at least one of a metal (e.g., tungsten, copper, or aluminum), a conductive metal nitride (e.g., titanium nitride or tantalum nitride), and a transition metal (e.g., titanium or tantalum).

Third contacts 166 may be formed on the strapping lines 160 so as to be connected to the strapping lines 160. A common source line CSL may be formed on the third contacts 166 so as to be connected to the third contacts 166. Thus, the common source line CSL may be electrically connected to the strapping lines 160 through the third contacts 166. The common source line CSL and the third contacts 166 may be formed of at least one of a metal (e.g., tungsten, copper, or aluminum), a conductive metal nitride (e.g., titanium nitride or tantalum nitride), and a transition metal (e.g., titanium or tantalum).

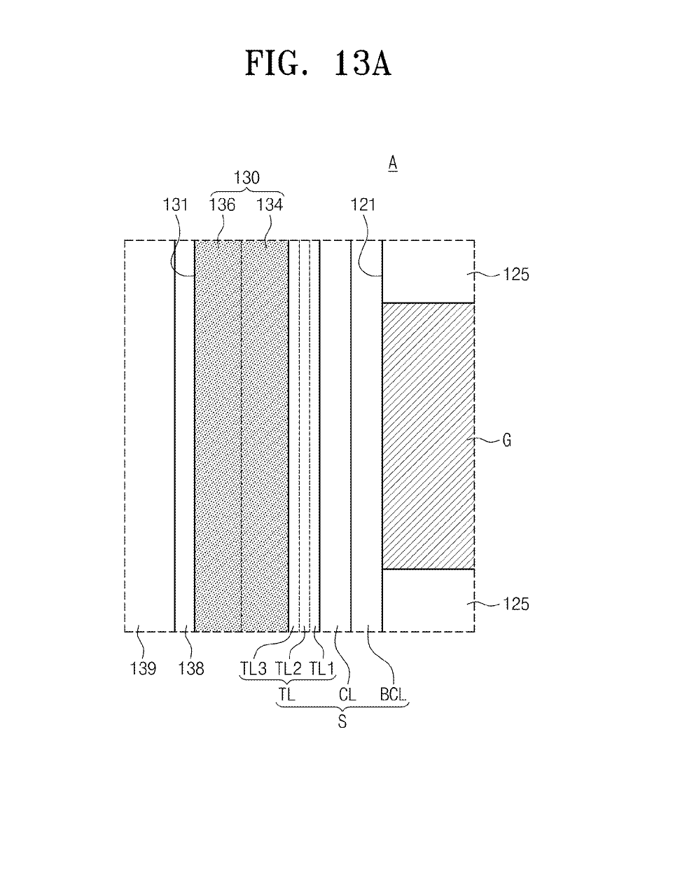

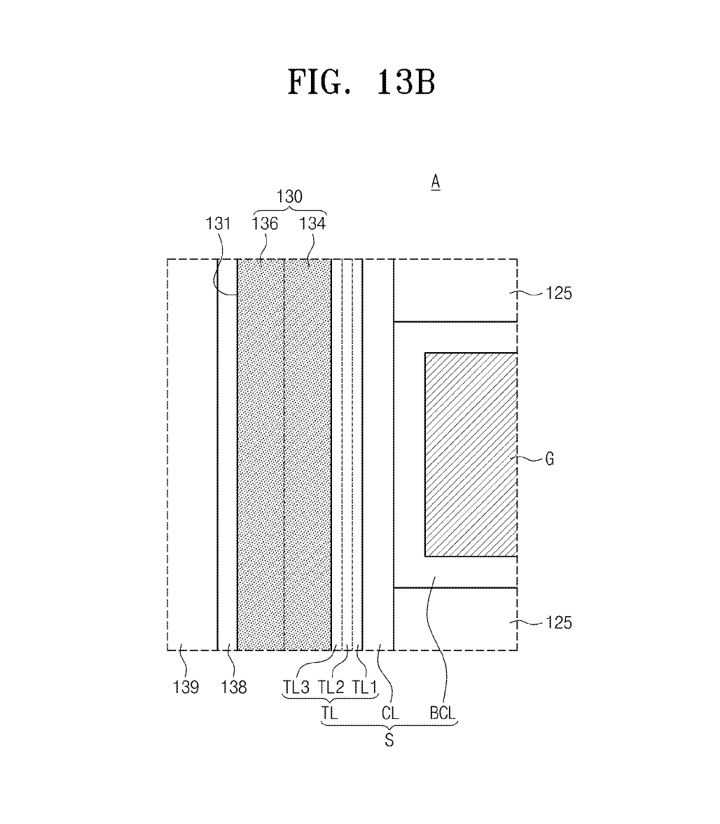

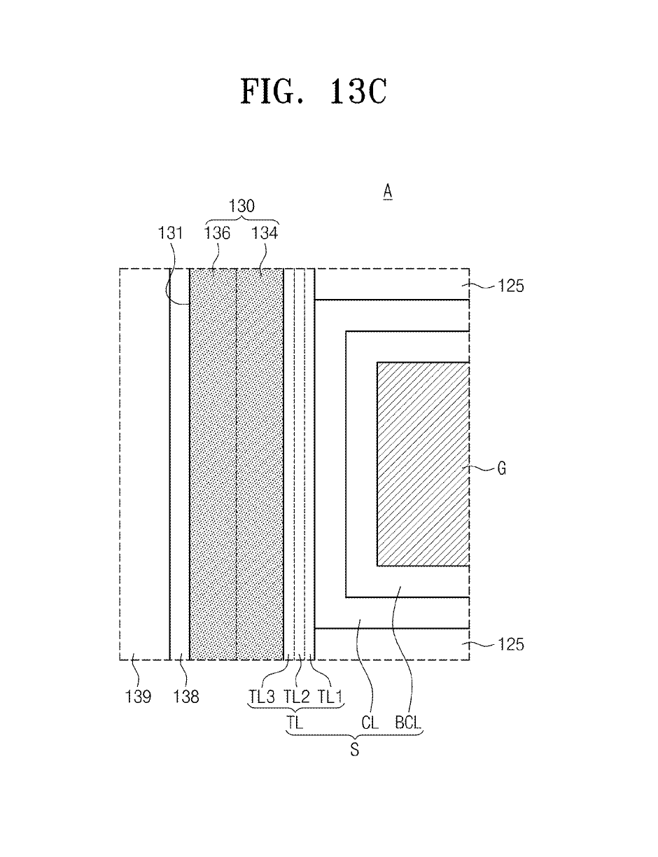

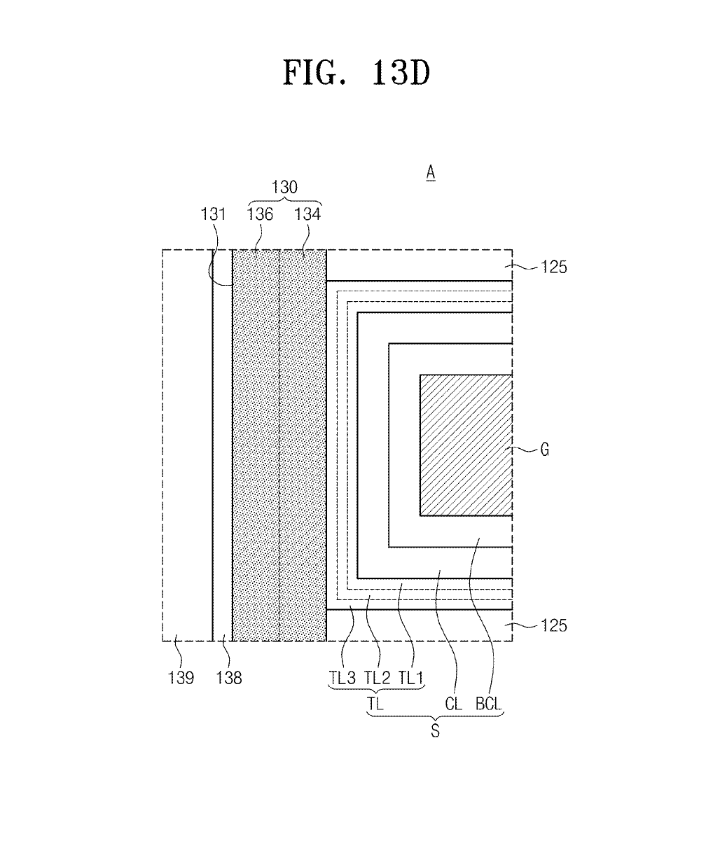

As described with reference to FIG. 4D, the data storage element S, e.g., a tunnel dielectric TL, charge storage layer CL and the blocking dielectric BCL, may be interposed between the active pillar 130 and the second to sixth gate electrodes G2 to G6. However, the structure of the data storage element S is not limited to including any of the examples of the tunnel dielectric TL, the charge storage layer CL and the blocking dielectric BCL described above. Various other examples of the data storage element S will be described hereinafter with reference to FIGS. 13A, 13B, 13C, and 13D.

In the example illustrated in FIG. 13A, the tunnel dielectric TL, the charge storage layer CL and the blocking dielectric BCL extend between the active pillar 130 and the insulating patterns 125. Alternatively, as illustrated in FIG. 13B, the blocking dielectric BCL extends between each of the second to sixth gate electrodes G2 to G6 and the insulating patterns 125. The blocking dielectric BCL may not be provided between the active pillar 130 and the insulating patterns 125. In still another example, as illustrated in FIG. 13C, the charge storage layer CL and the blocking dielectric BCL extend between each of the second to sixth gate electrodes G2 to G6 and the insulating patterns 125. The charge storage layer CL and the blocking dielectric BCL may not be provided between the active pillar 130 and the insulating patterns 125. In yet another embodiment, as illustrated in FIG. 13D, the tunnel dielectric TL, the charge storage layer CL and the blocking dielectric BCL extend between each of the second to sixth gate electrodes G2 to G6 and the insulating patterns 125. The tunnel dielectric layer TL, the charge storage layer CL and the blocking dielectric layer BCL may not be provided between the active pillar 130 and the insulating patterns 125.

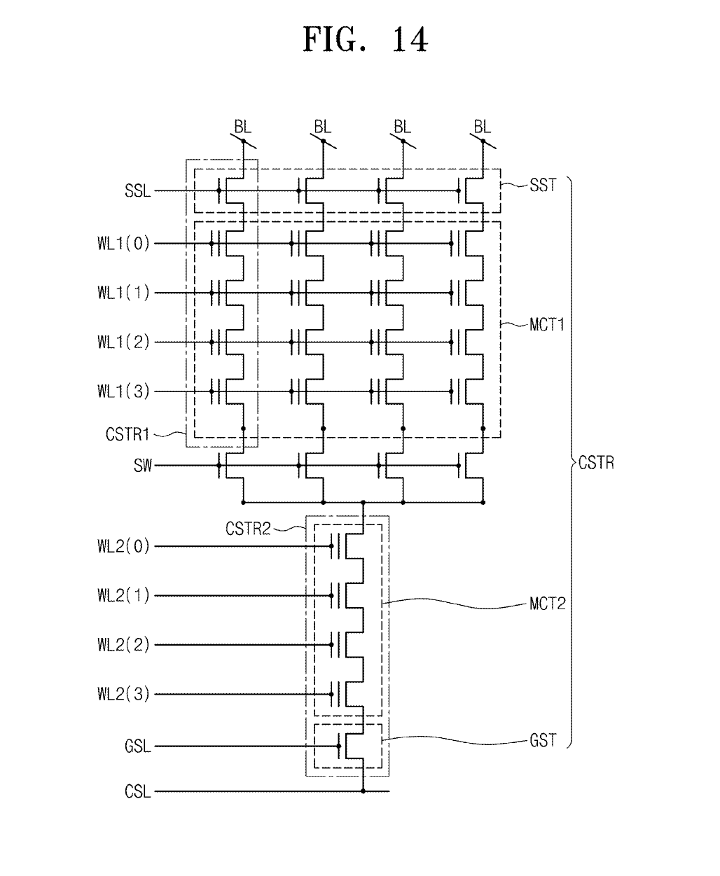

FIG. 14 is a circuit diagram of another example of a cell array of a memory block of FIG. 2, i.e., of a semiconductor device, according to the inventive concepts.

Referring to FIG. 14, the cell array may include a common source line CSL, a plurality of bit lines BL, and a cell string CSTR array between the common source line CSL and the bit lines BL.

The common source line CSL may be a conductive layer disposed on a substrate, and the bit lines BL may be conductive patterns (e.g., metal lines) disposed on the substrate.

The cell string array CSTR may include a plurality of upper strings CSTR1 respectively connected to the bit lines BL and a single lower string CSTR2 connected to the common source line CSL. The plurality of upper strings CSTR1 may be connected in common to the single lower string CSTR2. The upper strings CSTR1 may be connected in common to the lower string CSTR2 through switching elements SW. Thus, the same electrical voltage may be applied to the switching elements SW connected to the upper strings CSTR1.

Each of the upper strings CSTR1 may include a string selection transistor SST connected to each of the bit lines BL and a plurality of upper memory cell transistors MCT1 disposed between the string selection transistor SST and the switching element SW. The string selection transistor SST and the upper memory cell transistors MCT1 may be connected in series to each other. The lower string CSTR2 may include a ground selection transistor GST connected to the common source line CSL and a plurality of lower memory cell transistors MCT2 disposed between the ground selection transistor GST and the switching elements SW. The ground memory cell transistors GST and the lower memory cell transistors MCT2 may be connected in series to each other.

A string selection line SSL and upper word lines WL1(0) to WL1(3) which are disposed between the bit lines BL and the switching elements SW may serve as gate electrodes of the string selection transistor SST and the upper memory cell transistors MCT1, respectively. A ground selection line GSL and lower word lines WL2(0) to WL2(3) which are disposed between the common source line CSL and the switching elements SW may serve as gate electrodes of the ground selection transistor GST and the lower memory cell transistors MCT2, respectively. Each of the upper and lower memory cell transistors MCT1 and MCT2 may include a data storage element.

The plurality of upper strings CSTR1 respectively connected to the bit lines BL may be connected in common to the single lower string CSTR2 which, in turn, is connected to the common source line CSL. Thus, the upper strings CSTR1 which include the string selection transistors SST respectively connected to the bit lines BL may share the ground selection transistor GST of the single lower string CSTR2. In other words, the upper strings CSTR1 which are connected to different bit lines BL and are operated independently of each other may be connected in common to the single lower string CSTR2 to share the ground selection transistor GST such that a highly integrated semiconductor device may be realized.

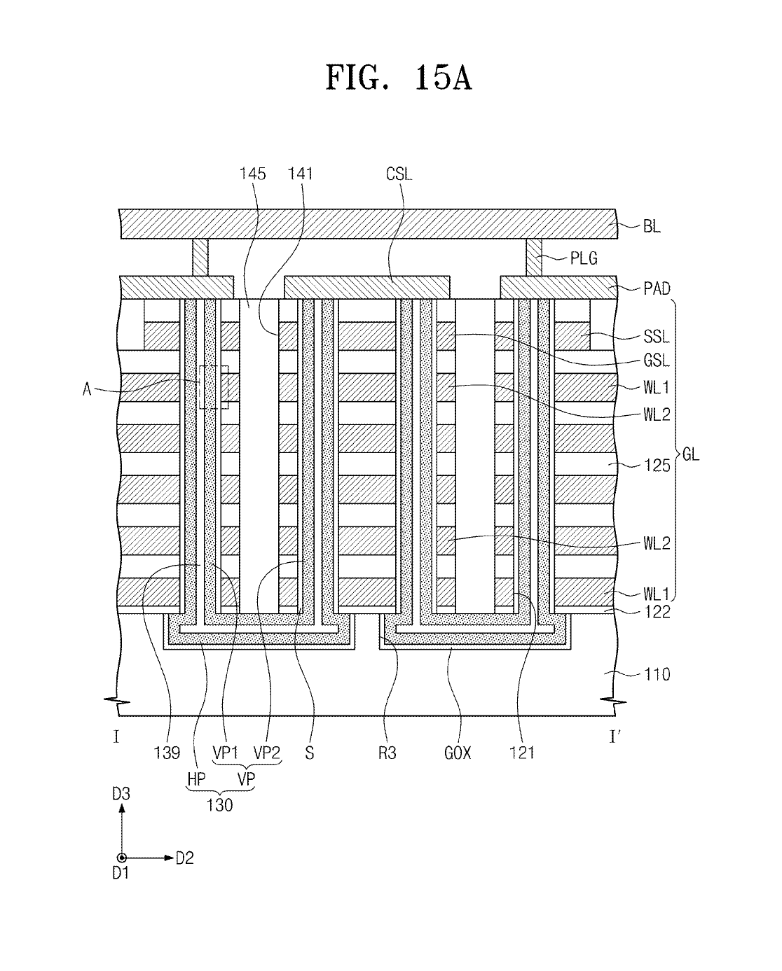

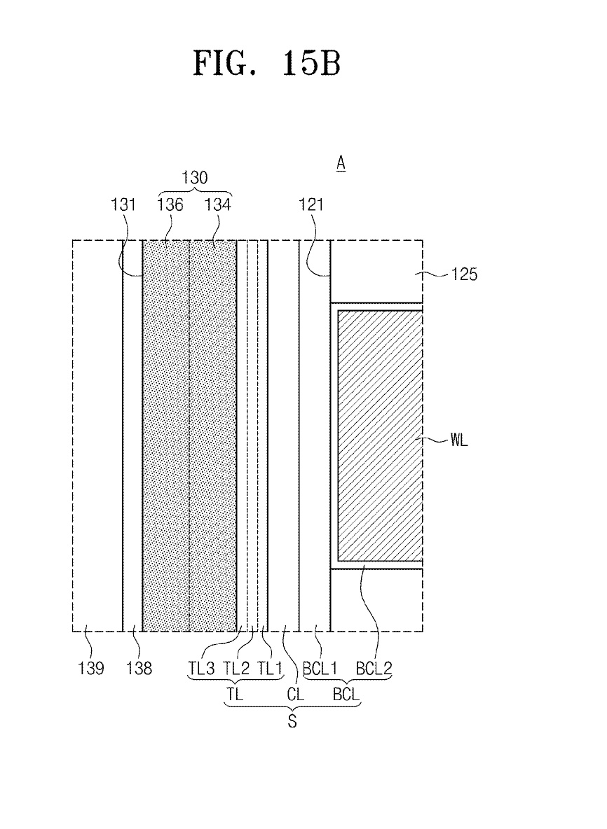

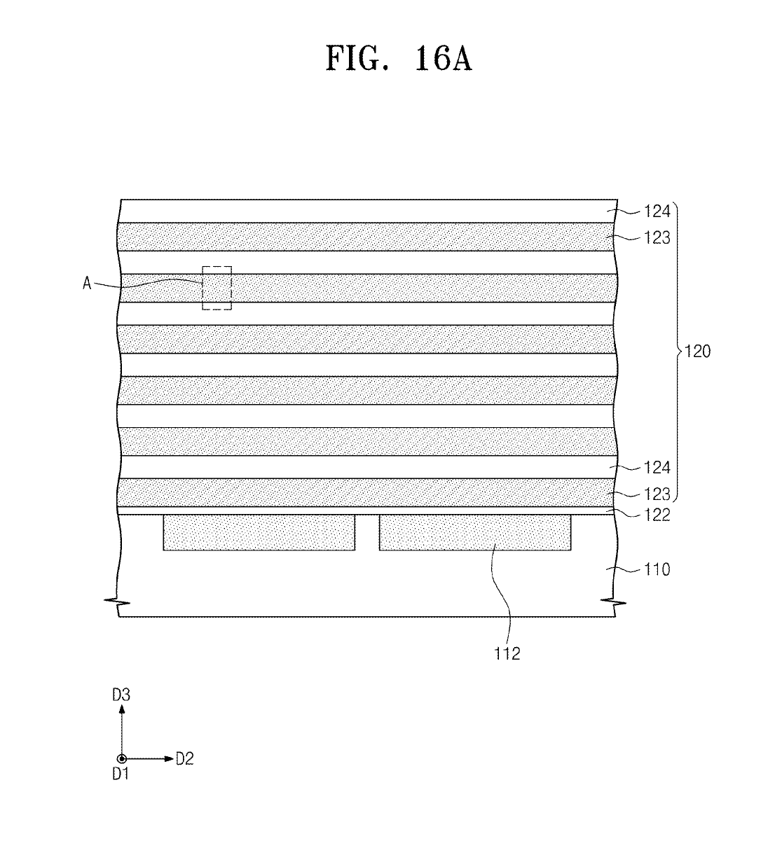

FIGS. 15A and 15B together illustrate embodiments of a memory device according to the inventive concepts. In these embodiments, elements similar to those of the previously described embodiments will be indicated by the same reference numerals or the same reference designators. Thus, elements similar to those already described above and designated by the same reference numerals may be only mentioned briefly hereinafter or not at all for the sake of brevity.

Referring to FIGS. 15A and 15B, a memory device according to the inventive concepts may include bit lines BL on a substrate 110, a gate stack GL between the substrate 110 and the bit lines BL, a common source line CSL between the gate stack GL and the bit lines BL, and a plurality of active pillars 130 extending through the gate stack GL. Each of the active pillars 130 may connect the bit line BL to the common source line CSL. A contact plug PLG and a pad PAD may be additionally provided between the gate stack GL and the bit line BL. A buffer dielectric layer 122 may be provided between the substrate 110 and the gate stack GL. The buffer dielectric layer 122 may include a silicon oxide layer.

The gate stack GL may extend in a first direction D1. The gate stack GL may have a plurality of discrete or spaced apart sections (each referred to hereinafter as a respective “gate stack”, therefore). More particularly, gate stacks GL may be spaced apart from each other in a second direction D2 intersecting the first direction D1 by isolation trenches 141 extending in the first direction D1. The second direction D2 may be perpendicular to the first direction D1. Each gate stack GL may include insulating patterns 125 and gate electrodes between the insulating patterns 125. The gate electrodes may include at least one of doped silicon, a metal (e.g., tungsten), a metal nitride, and a metal silicide. Each of the insulating patterns 125 may include a silicon oxide layer. The buffer dielectric layer 122 may be thinner than the insulating patterns 125.

The gate electrodes may be sequentially stacked on the substrate 110 in a direction (i.e., a third direction D3) perpendicular to a top surface of the substrate 110. The gate electrodes may include a string selection line SSL, word lines WL, and a ground selection line GSL. The string selection line SSL may be disposed between the word lines WL and the bit lines BL. The ground selection line GSL may be disposed between the common source line CSL and the word lines WL. The word lines WL may be sequentially stacked on the substrate 110. The string selection line SSL and the ground selection line GSL may be disposed on the word lines WL. The string selection line SSL and the ground selection GSL may be spaced apart from each other in the second direction D2 by the isolation trench 141. The word lines WL may include upper word lines WL1 disposed between the substrate 110 and the string selection line SSL and lower word lines WL2 disposed between the substrate 110 and the ground selection line GSL. The upper word lines WL1 may be spaced apart from the lower word lines WL2 in the second direction D2 by the isolation trench 141.

A device isolation pattern 145 may be provided between the string selection line SSL and the ground selection line GSL and between the upper word lines WL1 and the lower word lines WL2. The device isolation pattern 145 may be elongated in the first direction D1, e.g., may be a line-shaped pattern extending longitudinally in direction D1. The device isolation pattern 145 may fill the isolation trench 141 and may include at least one of a silicon oxide layer, a silicon nitride layer, and a silicon oxynitride layer.

The plurality of active pillars 130 may extend through the gate stack GL. The active pillars 130 may be arranged in the first direction D1 when viewed in plan.

Each of the active pillars 130 may include vertical portions VP penetrating the gate stack GL, and a horizontal portion HP connecting the vertical portions VP to each other under the gate stack GL. The vertical portions VP may be provided in vertical holes 121 in the gate stack GL. The horizontal portion HP may be provided in a horizontal recess R3 in an upper portion of the substrate 110 (a recess whose dimension in direction D2, i.e., in a plane parallel to the upper surface of the substrate is substantially greater than its dimension in direction D3, i.e., its depth). One of the vertical portions VP may be connected to the common source line CSL, and the other of the vertical portions VP may be connected to one of the bit lines BL. The horizontal portion HP may be provided between the substrate 110 and the gate stack GL to connect the vertical portions VP to each other.

More specifically, the vertical portions VP of each of the active pillars 130 may include a first vertical portion VP1 extending through the upper word lines WL1 and the string selection line SSL, and a second vertical portion VP2 extending through the lower word lines WL2 and the ground selection line GSL. The first vertical portion VP1 may be connected to one of the bit lines BL, and the second vertical portion VP2 may be connected to the common source line CSL. The horizontal portion HP may extend from a region directly under the upper word lines WL1 to a region directly under the lower word lines WL2 to connect the first vertical portion VP1 to the second vertical portion VP2.

Each of the active pillars 130 may include a semiconductor pattern that extends through the gate stack GL so as to be electrically coupled to the substrate 110. The semiconductor pattern of the vertical portion VP may line sides of the vertical holes 121. The semiconductor pattern of the horizontal portion HP may line the horizontal recess R3. The semiconductor pattern may include a semiconductor material. The semiconductor pattern may include a first semiconductor pattern 134 and a second semiconductor pattern 136 as was described previously.

Each of the active pillars 130 may have a hollow cylindrical shape, i.e., it may have an inner hole 131. The inner hole 131 of each of the active pillars 130 may be filled with a filling insulation layer 139. The filling insulation layer 139 may be, for example, a silicon oxide layer.

A data storage element S may be provided between the active pillar 130 and the gate stack GL. A gate insulating layer GOX may be provided between the substrate 110 and the active pillar 130. The gate insulating layer GOX may be a silicon oxide layer.

The active pillars 130, the filling insulation layer 139, and the data storage element S may have features similar to those of any of the examples described above, i.e., this semiconductor device may include any of the above-described measures to address the influence of the proximity of the insulation layer to the vertical channel on the current flow along the channel. For example, a fixed charge layer 138 may be provided between the active pillar 130 and the filling insulation layer 139. In addition, the first buffer insulating layer 137a may be provided between the fixed charge layer 138 and the active pillar 130. The second buffer insulating layer 137b may be provided between the fixed charge layer 138 and the filling insulation layer 139. (See FIG. 4E).

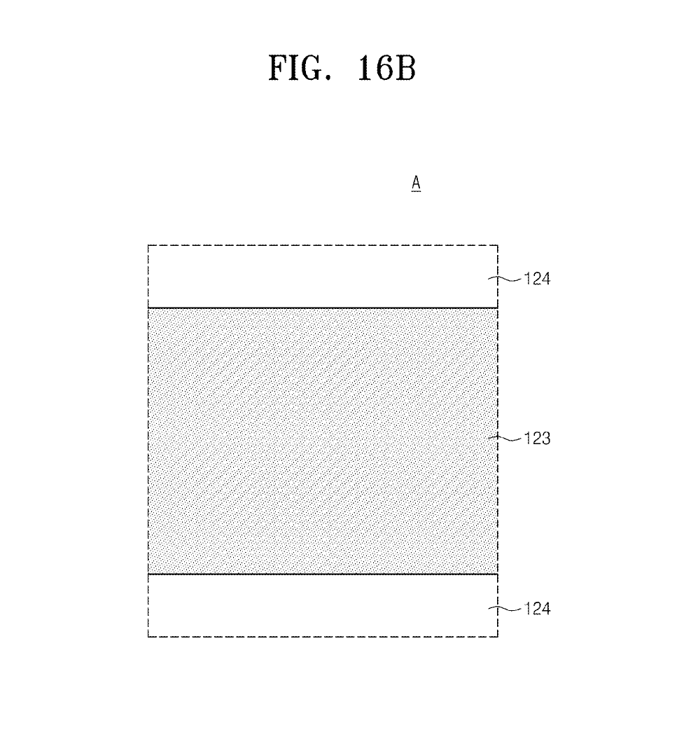

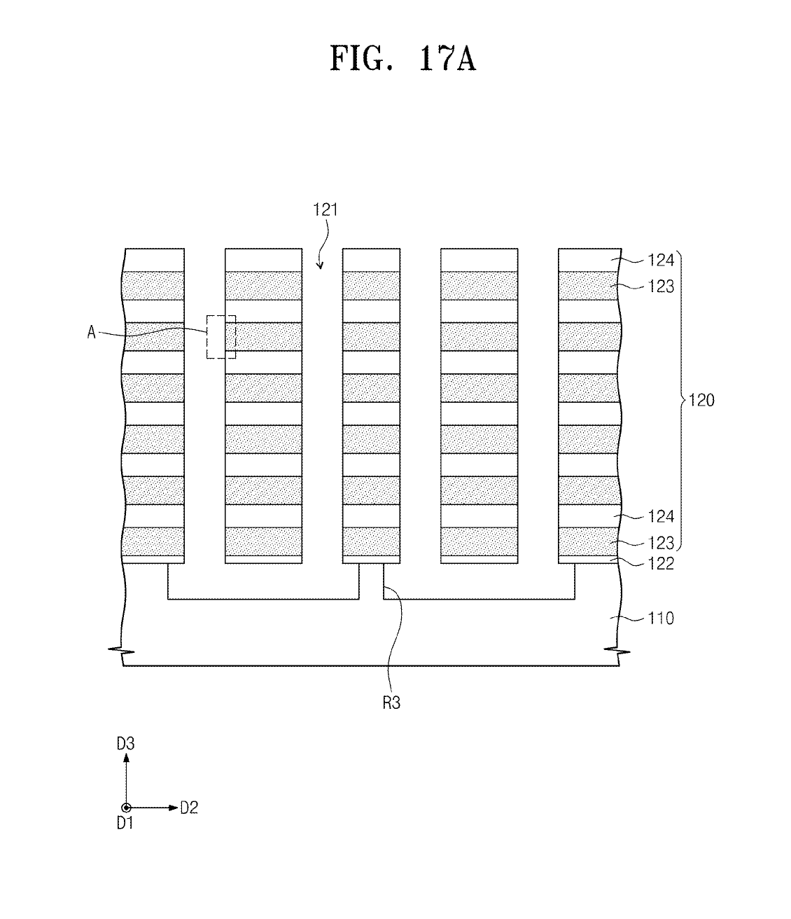

An embodiment of a method of manufacturing a memory device of this type will be described hereinafter with reference to FIGS. 16A to 21B. Some of the techniques or aspects thereof in common with those of the previously described embodiment may be mentioned only briefly or not described at all for the sake of brevity.

Referring to FIGS. 16A and 16B, a substrate 110 may be provided. The substrate 110 may be a semiconductor substrate having a first conductivity type (e.g., a P-type). The semiconductor substrate may include at least one selected of a single-crystalline silicon layer, silicon-on-insulator (SOB, a silicon layer formed on a silicon-germanium (SiGe) layer, a single-crystalline silicon layer formed on an insulating layer, and a poly-crystalline silicon layer formed on an insulating layer.

A buried sacrificial pattern 112 may be formed in the substrate 110, and then a preliminary gate stack 120 may be formed on the substrate 110.

The buried sacrificial pattern 112 may be formed of a material having an etch selectivity with respect to the preliminary gate stack 120. For example, the buried sacrificial patterns 112 may be formed as a silicon nitride layer, a silicon oxynitride layer, a germanium layer, or a silicon-germanium layer. The buried sacrificial pattern 112 may have an island shape and a plurality of such buried sacrificial patterns 112 may be formed. The buried sacrificial patterns 112 may be formed in a two-dimensional array. The preliminary gate stack 120 may include sacrificial layers 123 and insulating layers 124 which are alternately stacked on the substrate 110. A buffer dielectric layer 122 may be formed on the substrate 110 before the preliminary gate stack 120 is formed.

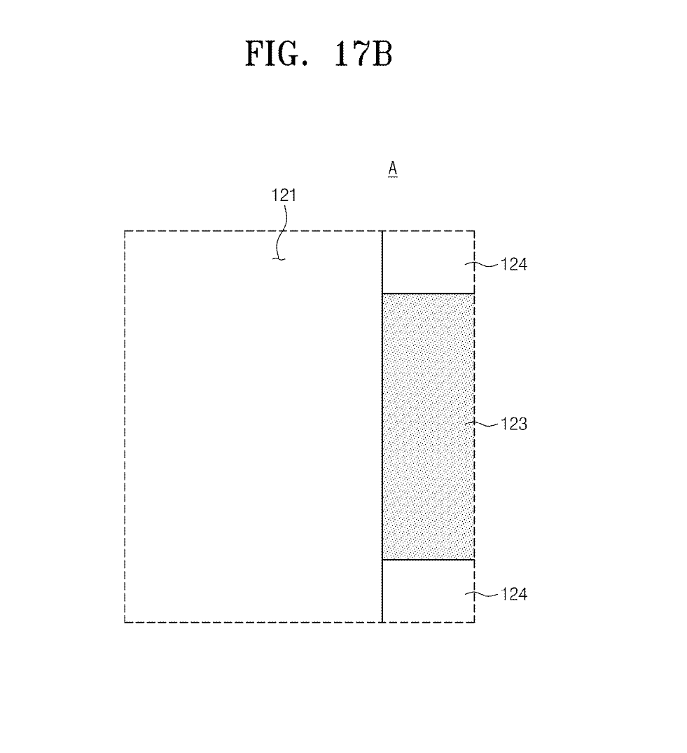

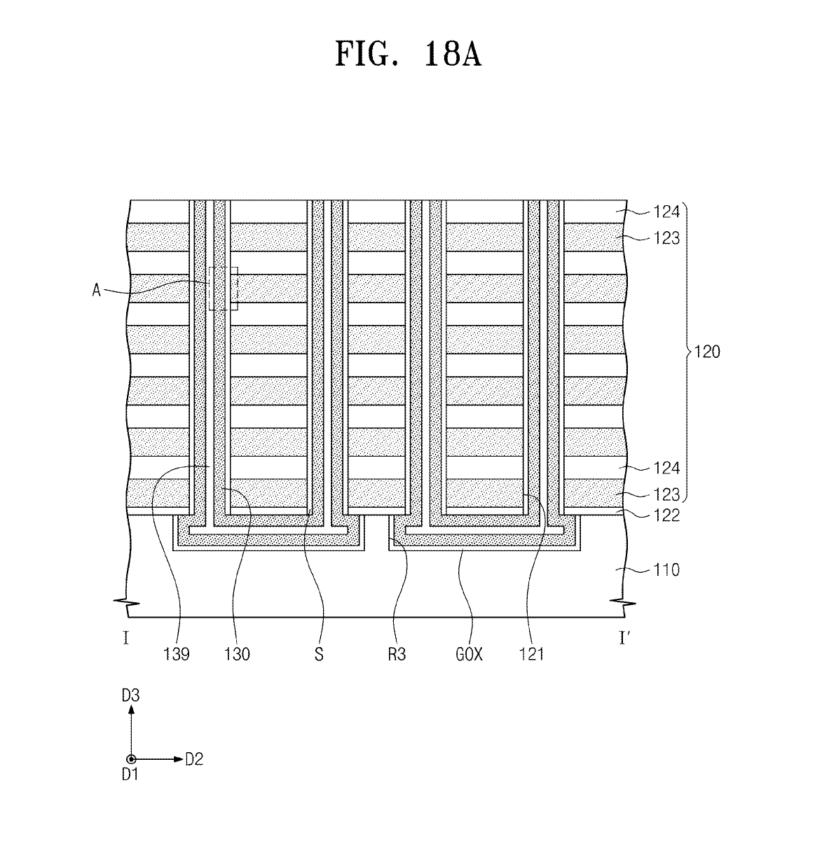

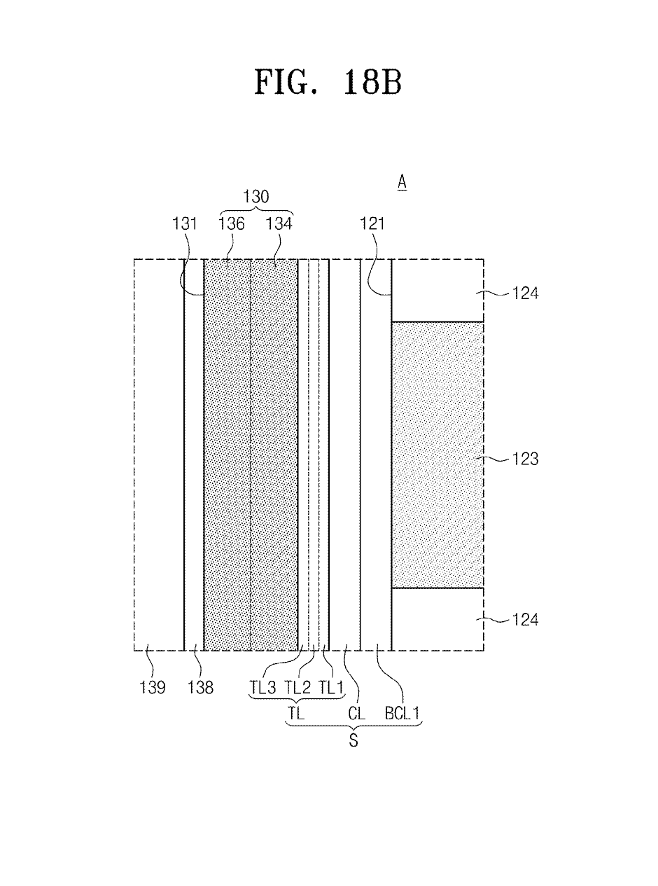

Referring to FIGS. 17A and 17B, vertical holes 121 may be formed through the preliminary gate stack 120. The vertical holes 121 may expose a top surface of the buried sacrificial pattern 112. The exposed buried sacrificial patterns 112 may be selectively removed to form a horizontal recess R3. Two vertical holes 121 may be formed on one buried sacrificial pattern 112. Thus, one horizontal recess R3 and a pair of the vertical holes 121 may together have a U-shaped cross section, as illustrated in FIG. 17A.

Referring to FIGS. 18A and 18B, an active pillar 130 may be formed to line the horizontal recess R3 and vertical holes 121. As illustrated in FIG. 18A, the active pillar 130 may not completely fill the horizontal recess R3 or either of the vertical holes 121. An inner hole 131 of the active pillar 130 may be filled with a filling insulation layer 139. A data storage element S may be formed before the active pillar 130 is formed. In addition, a gate insulating layer GOX may be formed alongside the horizontal recess R3 before the data storage element S is formed. The gate insulating layer GOX may be formed by thermally treating the substrate 110.

The active pillars 130, the filling insulation layer 139, a fixed charge layer 138, buffer insulating layers 137a and 137b, and the data storage element S may be formed as described with reference to FIGS. 7A to 9A and 7B to 9B. However, the anisotropic etching process described with reference to FIGS. 8A and 8B may be omitted.

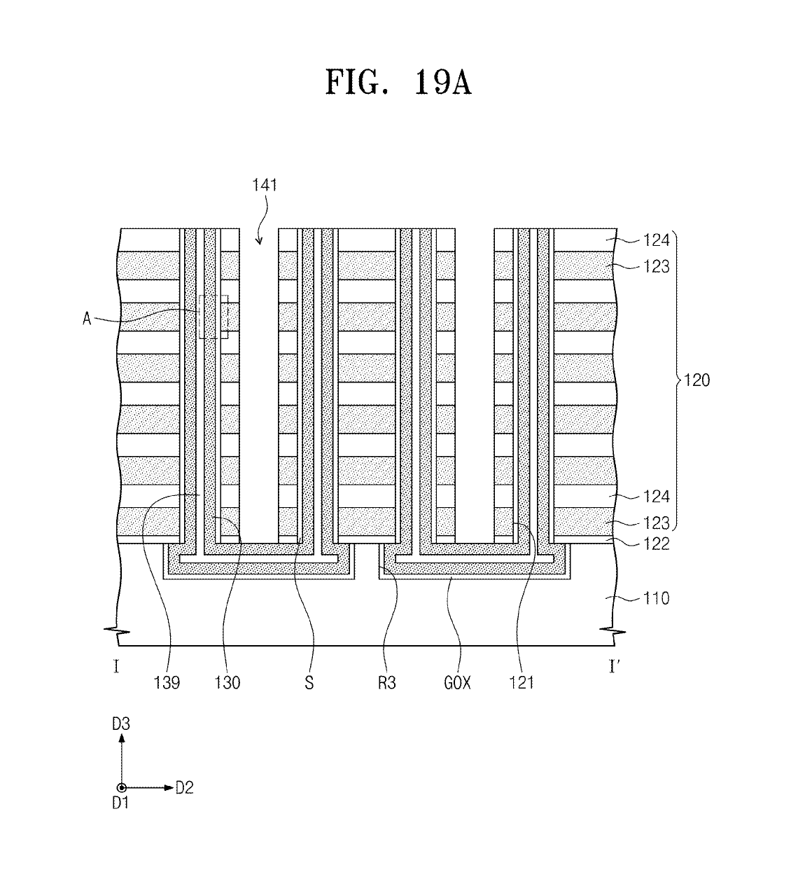

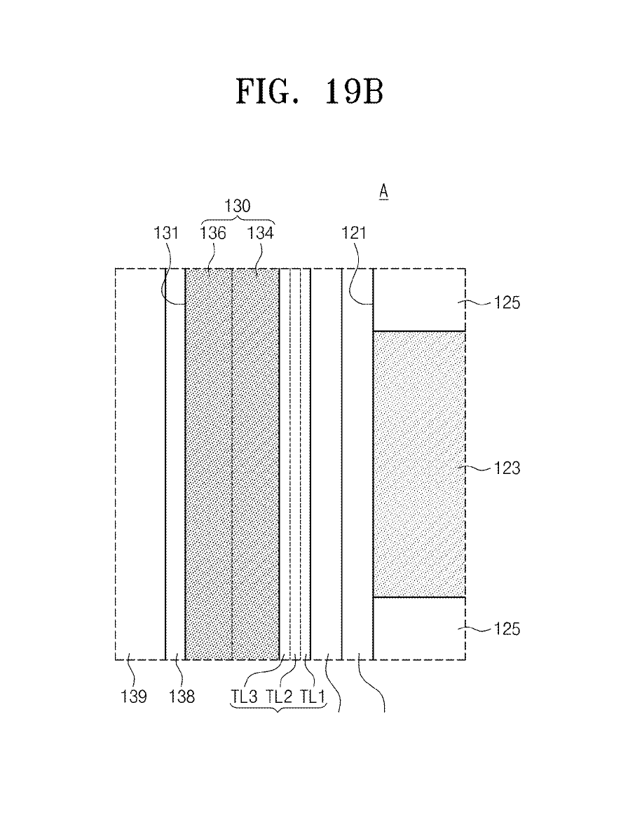

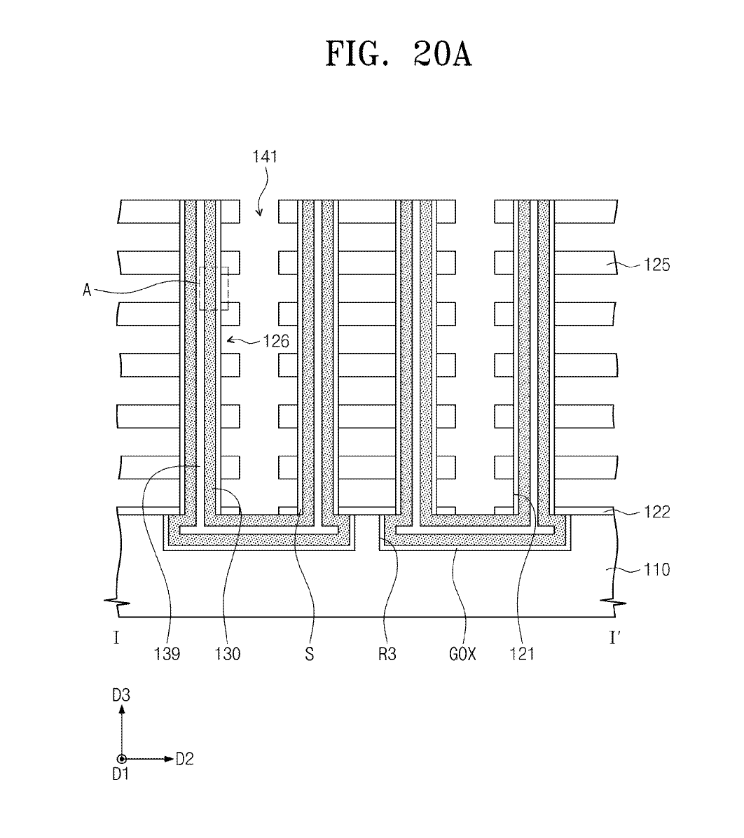

Referring to FIGS. 19A and 19B, the preliminary gate stack 120 may be patterned to form isolation trenches 141 intersecting the horizontal recesses R3. The isolation trench 141 may be formed between the pair of vertical holes 121 contiguous with one horizontal recess R3. When the isolation trenches 141 are formed, the insulating layers 124 may be patterned to form insulating patterns 125.

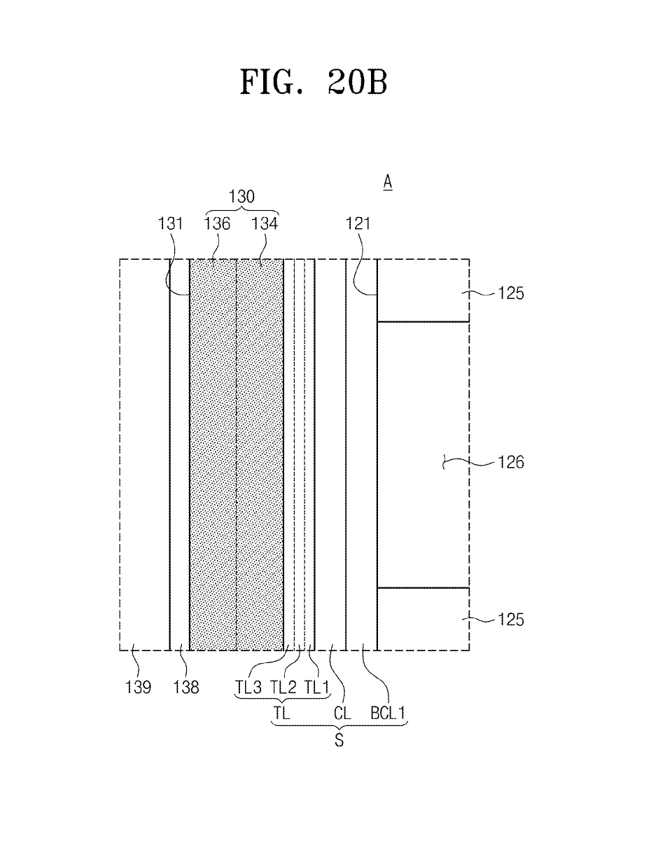

Referring to FIGS. 20A and 20B, the sacrificial layers 123 exposed by the isolation trenches 141 may be selectively removed to form gate regions 126.

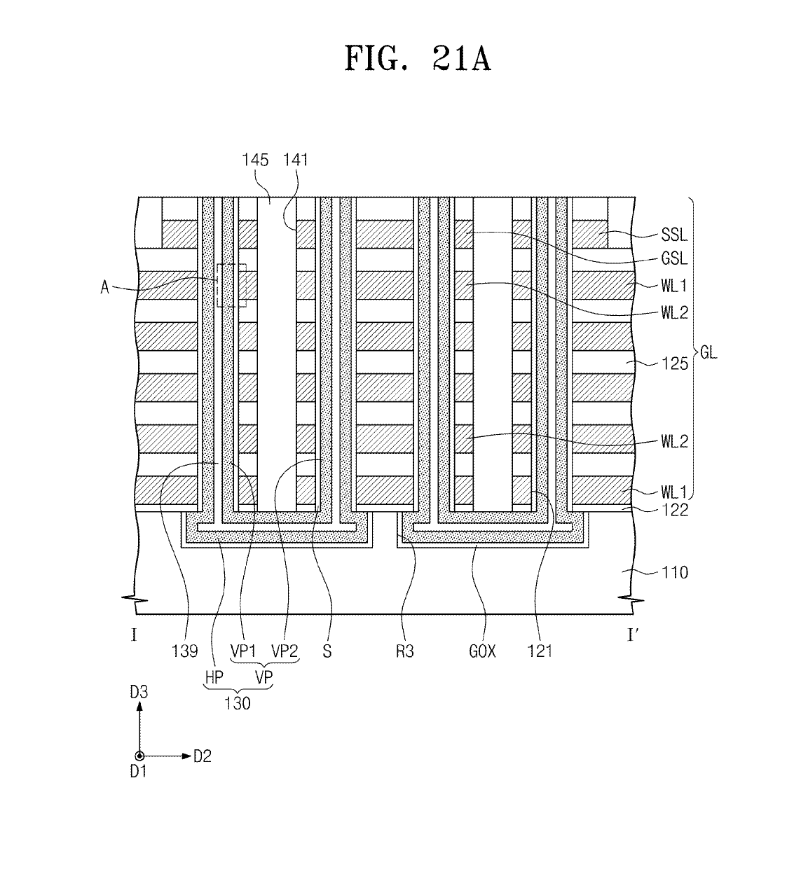

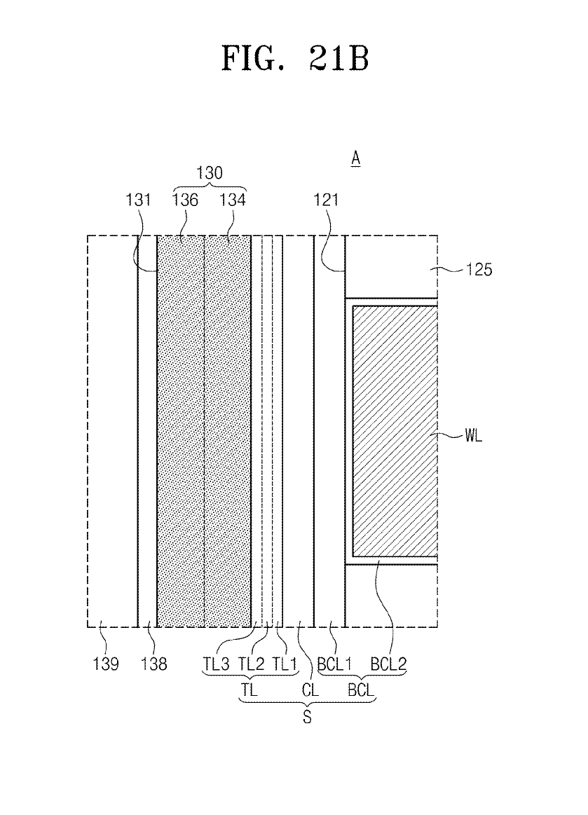

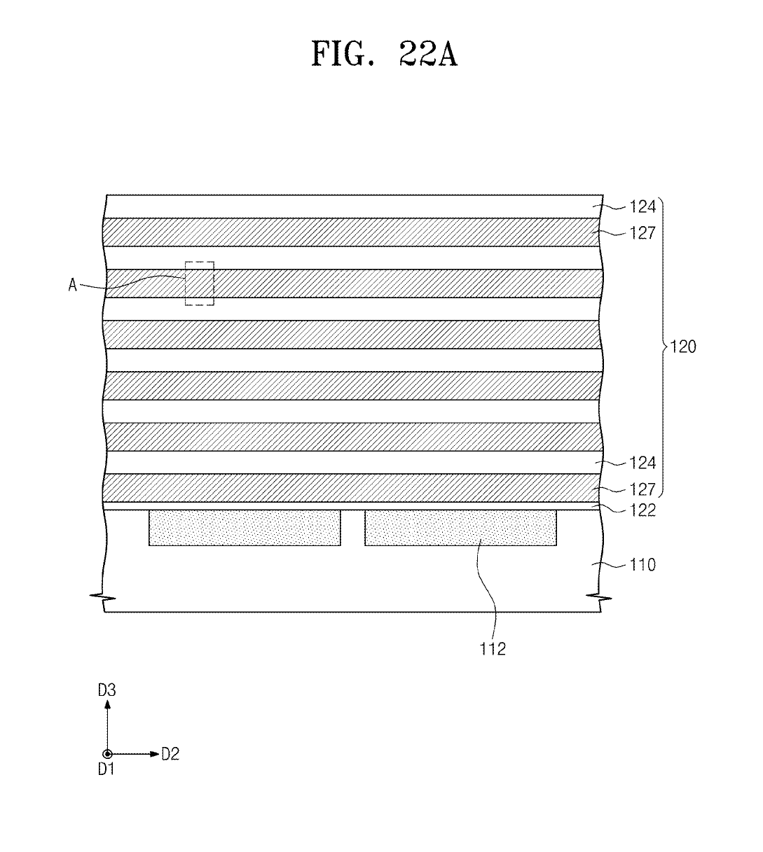

Referring to FIGS. 21A and 21B, conductive patterns may be formed in the gate regions 126 through the isolation trenches 141. The conductive patterns may be formed of at least one of a doped poly-crystalline silicon layer, a metal layer (e.g., a tungsten layer), and a metal nitride layer. For example, each of the conductive patterns may include a metal nitride layer and a metal layer on the metal nitride layer. The second blocking dielectric layer BCL2 may be formed before the conductive patterns are formed. The uppermost one of the conductive patterns may be patterned to define a string selection line SSL. Thus, a ground selection line GSL laterally spaced apart from the string selection line SSL may also be defined. The conductive patterns under the string and ground selection lines SSL and GSL may correspond to word lines WL. The isolation trench 141 may be filled with a device isolation pattern 145.

Referring again to FIGS. 15A and 15B, a pad PAD connected to the active pillar 130 and a common source line CSL may be formed. Subsequently, bit lines BL connected to the pads PAD may be formed. A contact plug PLG may be formed between the bit line BL and the pad PAD.

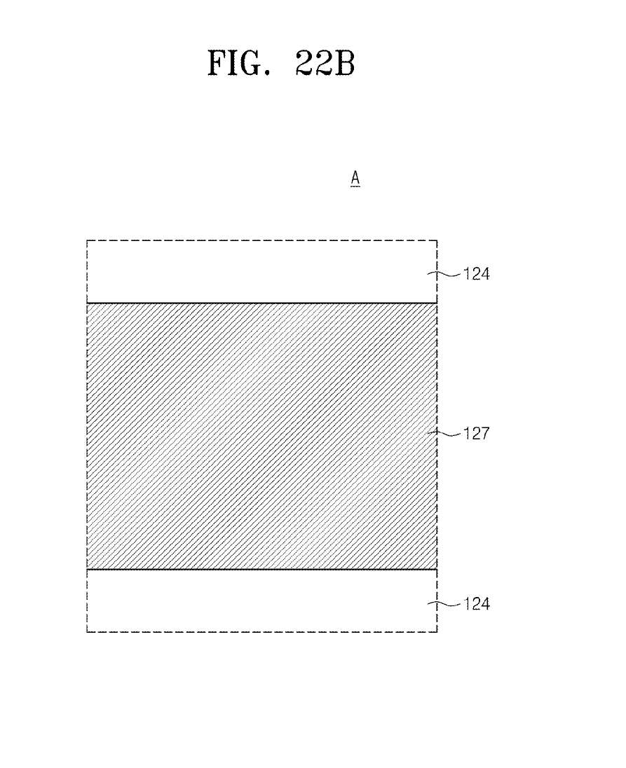

Another embodiment of a method of manufacturing a memory device will be described hereinafter with reference to FIGS. 22A to 24B. Again, techniques or features thereof similar to those already described above in connection with the previous as embodiments will be mentioned briefly or will not be described again for the sake of brevity.

Referring to FIGS. 22A and 22B, a substrate 110 may be provided. Buried sacrificial patterns 112 may be formed in the substrate 110. A buffer dielectric layer 122 may be formed on the substrate 110 and the buried sacrificial patterns 112. The buffer dielectric layer 122 may be a silicon oxide layer. A preliminary gate stack 120 may be formed on the buffer dielectric layer 122.

The buried sacrificial patterns 112 may be formed of a material having an etch selectivity with respect to the preliminary gate stack 120. The buried sacrificial patterns 112 may have island shapes and may be formed in a two-dimensional array.

The preliminary gate stack 120 may include insulating layers 123 and conductive layers 127 between the insulating layers 123. The insulating layers 123 may be silicon oxide layers. The conductive layers 127 may be formed of at least one of doped silicon, a metal (e.g., tungsten), a metal nitride, and a metal silicide.

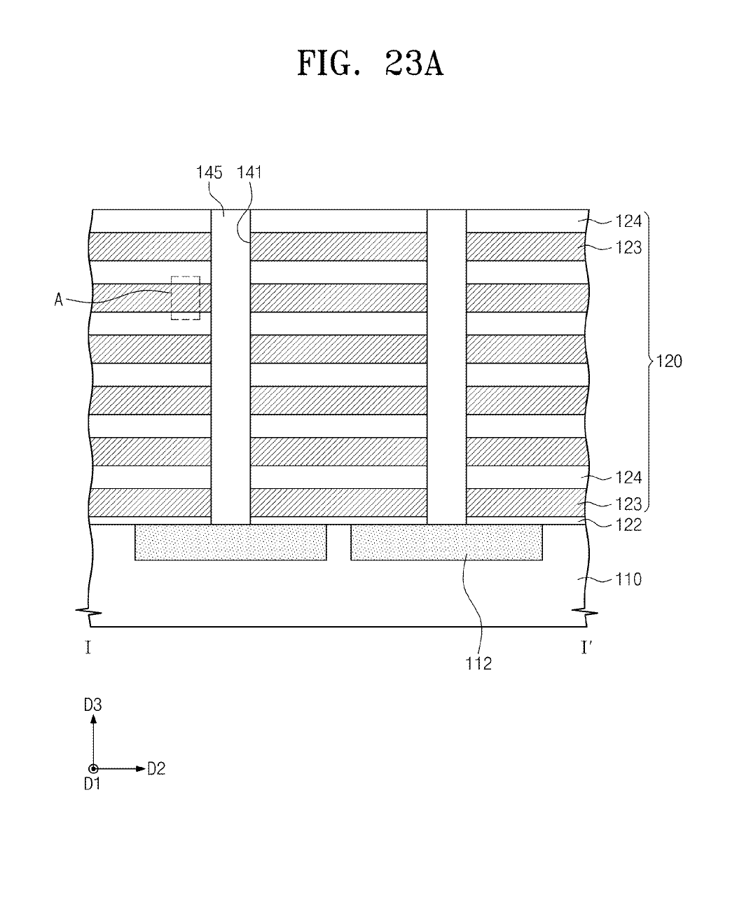

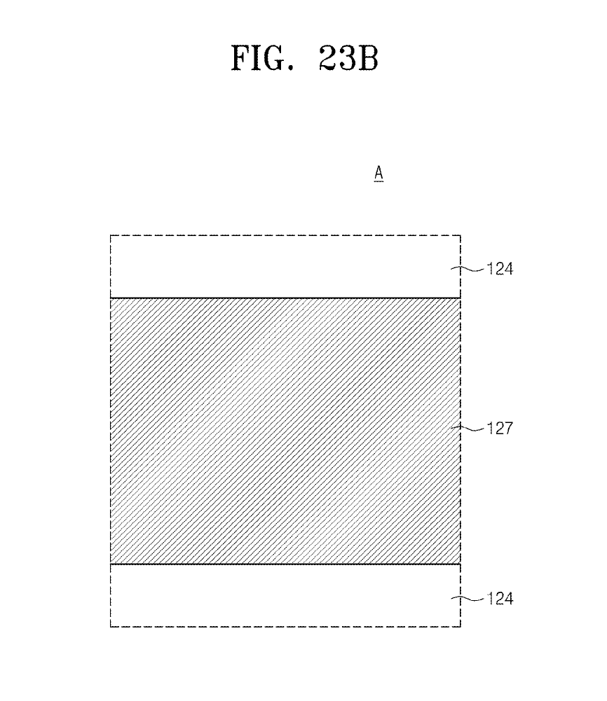

Referring to FIGS. 23A and 23B, isolation trenches 141 may be formed to expose the buried sacrificial patterns 112. The isolation trenches 141 may extend in the first direction D1. A device isolation pattern 145 may be formed in each of the isolation trenches 141. The device isolation pattern 145 may include a silicon oxide layer.

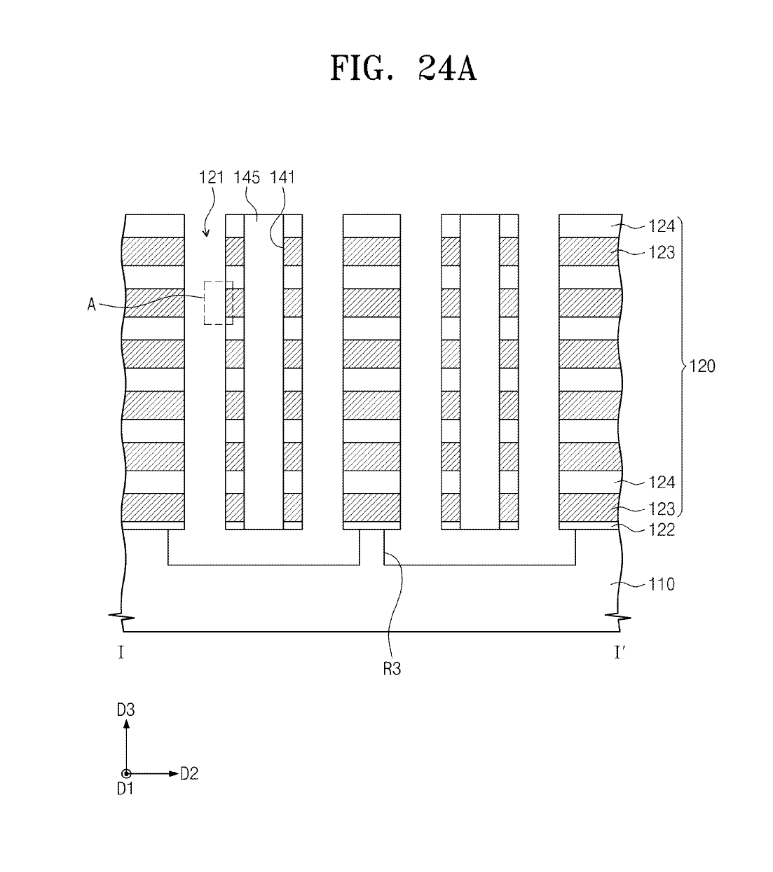

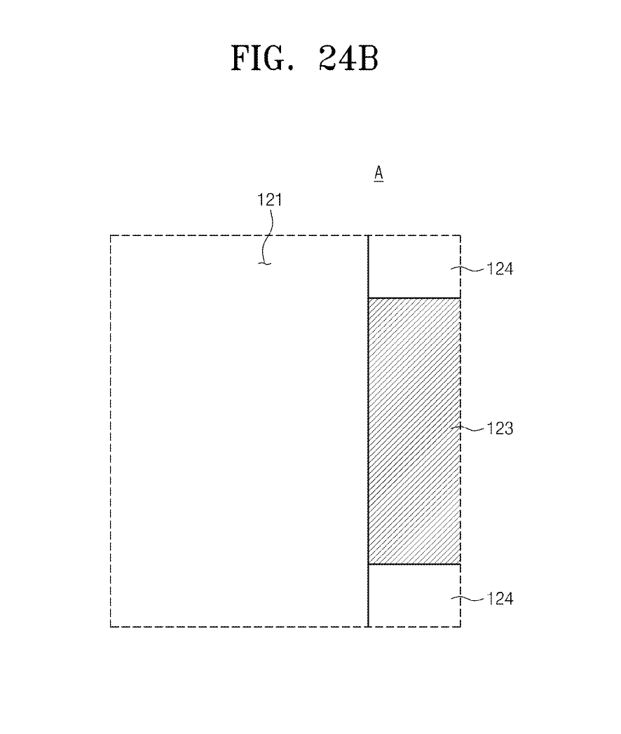

Referring to FIGS. 24A and 24B, vertical holes 121 may be formed through the preliminary gate stack 120. The vertical holes 121 may expose top surfaces of the buried sacrificial patterns 112. The exposed buried sacrificial patterns 112 may be selectively removed to form horizontal recesses R3. Two vertical holes 121 may be formed on one buried sacrificial pattern 112. Thus, one horizontal recess R3 and the two vertical holes contiguous therewith may have a U-shaped cross section, as illustrated in FIG. 24A.

Referring again to FIGS. 15A and 15B, active pillars 130, data storage element S, the filling insulation layer 139 may be formed as described previously. Fixed charge layer 138 and buffer insulating layers 137a and 137b may also be formed.

Subsequently, string selection line SSL, ground selection line GSL, the common source line CSL, pad PAD, bit line BL may be formed again, according to the descriptions above.

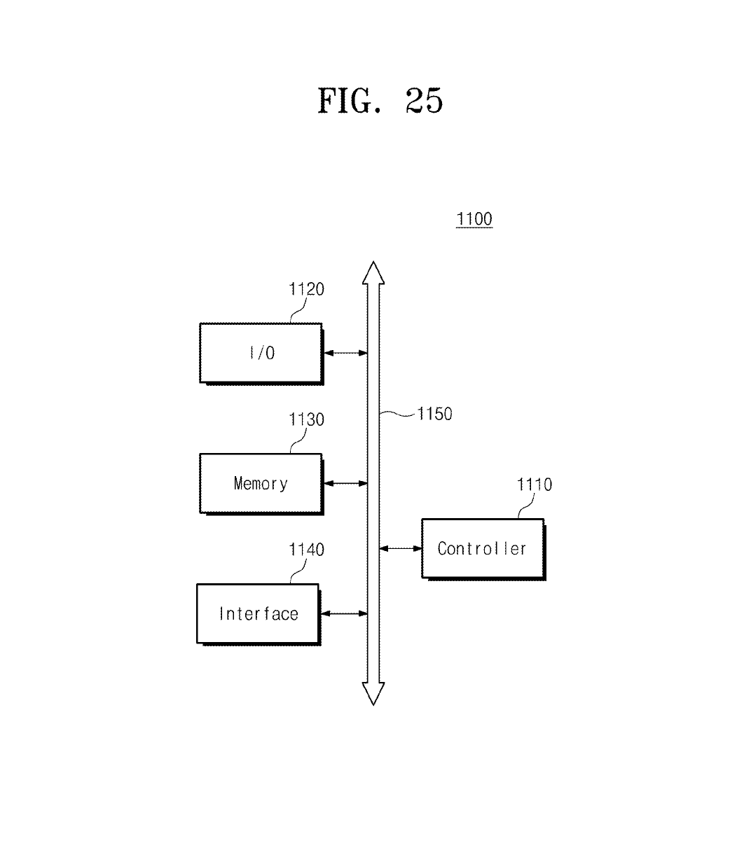

FIG. 25 is a schematic block diagram illustrating an example of an electronic system including a memory device according to any of the embodiments of the inventive concepts.

Referring to FIG. 25, an electronic system 1100 according to embodiments of the inventive concept may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical data are transmitted. The memory device 1130 may include at least one of the memory devices according to the aforementioned embodiments of the inventive concepts.

The controller 1110 may include at least one of a microprocessor, a digital signal processor, a microcontroller, or other logic devices having a similar function to any one thereof. The I/O unit 1120 may include a keypad, a keyboard and/or a display device. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. Although not shown in the drawings, the electronic system 1100 may further include a fast dynamic random access memory (fast DRAM) device and/or a fast static random access memory (fast SRAM) device which acts as a working memory for improving an operation of the controller 1110.

The electronic system 1100 may be applied to a personal digital assistant (PDA), a portable computer, a web tablet, a wireless phone, a mobile phone, a digital music player, a memory card, or other electronic products receiving and/or transmitting information data by wireless.

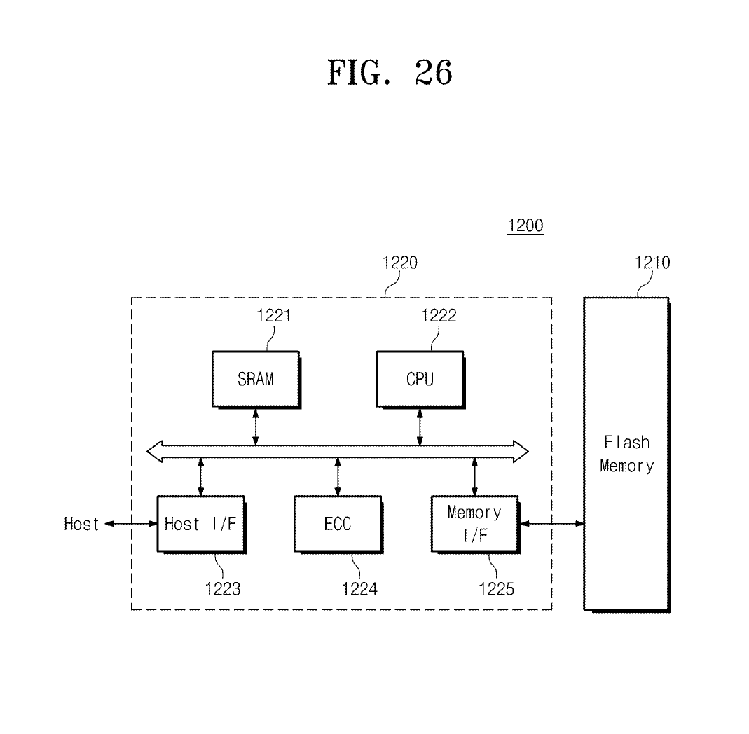

FIG. 26 is a schematic block diagram illustrating an example of a memory card including a memory device according to any of the embodiments of the inventive concepts.

Referring to FIG. 26, a memory card 1200 includes a memory device 1210. The memory device 1210 may include at least one of the memory devices of the aforementioned embodiments of the inventive concepts. In addition, the memory device 1210 may further include another type of a semiconductor memory device (e.g., a DRAM device and/or a SRAM device). The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as a working memory of the CPU 1222. Moreover, the memory controller 1220 may further include a host interface unit 1223 and a memory interface unit 1225. The host interface unit 1223 may include a data communication protocol between the memory card 1200 and the host. The memory interface unit 1225 may connect the memory controller 1220 to the memory device 1210. Furthermore, the memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may be realized as solid state disks (SSD) which are used as hard disks of computer systems.

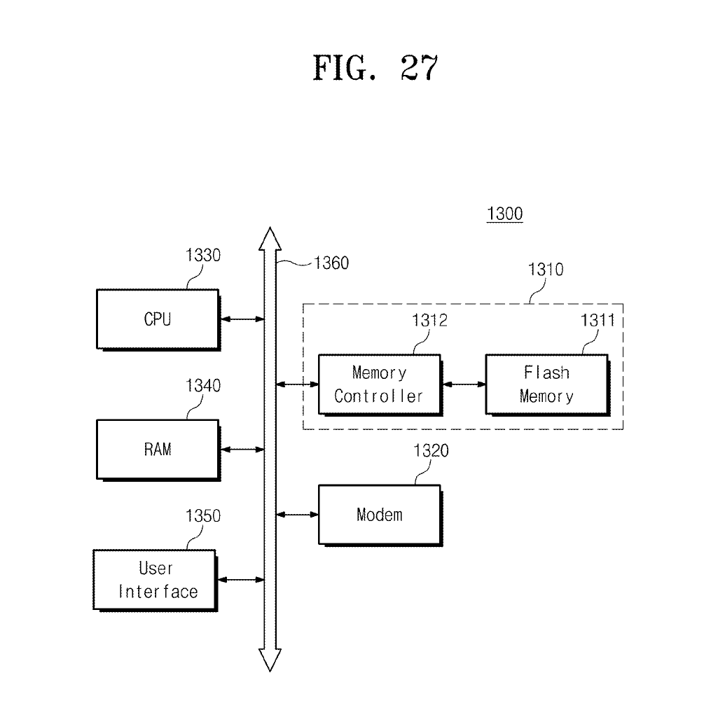

FIG. 27 is a schematic block diagram illustrating an example of an information processing system including a memory device according to any of the embodiments of the inventive concepts.

Referring to FIG. 27, a flash memory system 1310 may be installed in an information processing system 1300 such as a mobile device or a desk top computer. The flash memory system 1310 may include a flash memory device 1311 and a memory controller 1312. The flash memory device 1311 may include at least one of the memory devices according to embodiments of the inventive concepts. The information processing system 1300 may include a modem 1320, a central processing unit (CPU) 1330, a random access memory (RAM) 1340, and a user interface unit 1350 that are electrically connected to the flash memory system 1310 through a system bus 1360. The flash memory system 1310 may store data processed by the CPU 1330 or data inputted from an external system. In some embodiments, the flash memory system 1310 may be realized as a solid state disk (SSD). In this case, the information processing system 1300 may stably store massive data into the flash memory system 1310. In addition, as reliability of the flash memory system 1310 increases, the flash memory system 1310 may reduce a resource consumed for correcting errors. Thus, the flash memory system 1310 may provide a fast data communication function to the information processing system 1300. Even though not shown in the drawings, the information processing system 1300 may further include an application chipset, a camera image processor (CIS), and/or an input/output unit.

As described above, a semiconductor memory device according to the inventive concepts may have an improved characteristic between the active pillar providing a vertical channel and the filling insulation layer. In addition, the amount of the current flowing adjacent to the filling insulation layer may be minimal As a result, an improved 3D non-volatile memory device may be realized according to the inventive concepts.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A memory device comprising:
a substrate;
a stack including gate electrodes vertically stacked on the substrate, the stack having a vertical hole exposing a portion of the substrate;
an active pillar including a bottom portion disposed in a lower region of the vertical hole, and a vertical portion extending along sides of the vertical hole, the active pillar having an inner hole;
a charge storage section interposed between the active pillar and the gate electrodes;
a blocking dielectric interposed between the charge storage section and the gate electrodes;
a tunnel dielectric interposed between the charge storage and the active pillar;
filling insulation filling the inner hole; and
a fixed charge layer interposed between the filling insulation and the active pillar,
wherein the fixed charge layer extends onto the bottom portion of the active pillar, and
the vertical portion of the active pillar is thicker than the bottom portion of the active pillar.

2. The memory device of claim 1, wherein the active pillar includes silicon or germanium, and
the filling insulation includes a silicon oxide layer.

3. The memory device of claim 2, wherein the fixed charge layer comprises an aluminum oxide layer, an aluminum nitride layer, or an aluminum oxynitride layer.

4. The memory device of claim 2, wherein the fixed charge layer comprises a silicon nitride layer, a boron nitride layer, a doped silicon layer, a doped silicon oxide layer, or an aluminum nitride layer.

5. The memory device of claim 2, further comprising:
a first insulating buffer interposed between the fixed charge layer and the active pillar,
wherein the first insulating buffer is of material differing from that of the material the fixed charge layer.

6. The memory device of claim 5, wherein the first insulating buffer comprises a silicon oxide layer or a silicon nitride layer.

7. The memory device of claim 2, further comprising:
a second insulating buffer interposed between the fixed charge layer and the filling insulation,
wherein the second insulating buffer is of material differing from that of the material of each of the fixed charge layer and the filling insulation.

8. The memory device of claim 7, wherein the second insulating buffer comprises a silicon oxide layer or a silicon nitride layer.

9. The memory device of claim 7, wherein the second insulating buffer has an etch selectivity with respect to the filling insulation.

10. The memory device of claim 9, wherein the second insulating buffer is a silicon oxide layer, and
a wet etch rate of the second insulating buffer with respect to a predetermined wet etch solution, is greater than that of the filling insulation.

11. The memory device of claim 1, further comprising:
a lower semiconductor pattern disposed in a lower region of the vertical hole,
wherein the lower semiconductor pattern is in contact with the substrate.

12. The memory device of claim 11, wherein a portion of the substrate exposed by the vertical hole is a recessed portion defining a recess in an upper surface of the substrate, and
a lower portion of the lower semiconductor pattern extends into the recess.

13. The memory device of claim 11, wherein a top portion of the lower semiconductor pattern is recessed so as to define a recess in a top surface of the lower semiconductor pattern, and
the bottom portion of the active pillar extends into the recess in the top surface of the lower semiconductor pattern.

14. The memory device of claim 11, wherein a top surface of the lower semiconductor pattern is situated at a level higher than that of a top surface of a lowermost one of the gate electrodes.

15. The memory device of claim 1, wherein the filling insulation is of doped silicon oxide.

16. (canceled)

17. A memory device comprising:
a substrate;
a stack including gate electrodes vertically stacked on the substrate, the stack having a vertical hole exposing a portion of the substrate;
an active pillar disposed in the vertical hole and having an inner hole;
a charge storage section interposed between the active pillar and the gate electrodes;
a blocking dielectric interposed between the charge storage section and the gate electrodes;
a tunnel dielectric interposed between the charge storage section and the active pillar; and
filling insulation filling the inner hole,
wherein the active pillar includes a first semiconductor pattern adjacent to the filling insulation layer, and a second semiconductor pattern interposed between the first semiconductor pattern and the tunnel dielectric, and
a dopant concentration of the second semiconductor pattern is different from that of the first semiconductor pattern.

18. The memory device of claim 17, wherein the active pillar contains P-type dopants, and
the dopant concentration of the first semiconductor pattern is higher than that of the second semiconductor pattern.

19. (canceled)

20. A memory device comprising:
a substrate;
a stack including gate electrodes vertically stacked on the substrate, the stack having a vertical hole exposing a portion of the substrate;
an active pillar disposed in the vertical hole and having an inner hole;
a charge storage layer interposed between the active pillar and the gate electrodes;
a blocking dielectric interposed between the charge storage layer and the gate electrodes;
a tunnel dielectric interposed between the charge storage layer and the active pillar; and
filling insulation layer filling the inner hole,
wherein the active pillar includes a first semiconductor pattern adjacent to the filling insulation layer, and a second semiconductor pattern interposed between the first semiconductor pattern and the tunnel dielectric, and
the second semiconductor pattern is of material differing from the material of the first semiconductor pattern.

21. The memory device of claim 20, wherein the second semiconductor pattern comprises a layer of silicon-germanium, and
the first semiconductor pattern comprises a layer of silicon.

22. The memory device of claim 20, wherein each of the first and second semiconductor patterns comprises silicon-germanium, and
the germanium concentration of the second semiconductor pattern is higher than that of the first semiconductor pattern.

23. (canceled)
